(19) United States
(12) Patent Application Publication
(10) Pub. No.: US 2023/0073471 A1
(43) Pub. Date: Mar. 9, 2023

(54) CONJUGATED POLYMER MATERIALS AND ORGANIC OPTOELECTRONIC DEVICE USING THE SAME

(71) Applicant: Raynergy Tek Incorporation, Hsinchu (TW)

(72) Inventors: CHUANG-YI LIAO, HSINCHU (TW); LIN-CHIEH CHENG, HSINCHU (TW); WEI-LONG Li, HSINCHU (TW); YU-TANG HSIAO, HSINCHU (TW)

(21) Appl. No.: 17/870,162

(22) Filed: Jul. 21, 2022

Related U.S. Application Data
(60) Provisional application No. 63/230,088, filed on Aug. 6, 2021.

(51) Int. Cl. C08F 28/06; H01L 51/50; H01L 51/00; C09K 11/06

(52) U.S. Cl. CPC C08F 28/06; C09K 11/06; H01L 51/0036; H01L 51/5004; H01L 51/5036; C09K 2211/1483

(57) ABSTRACT

An organic optoelectronic device comprises an active layer comprising a conjugated polymer material which comprises a structure of Formula I:

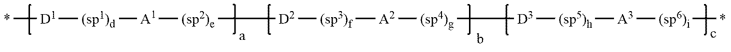

wherein

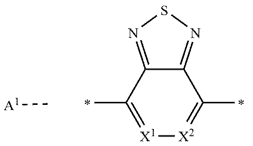

, and X¹ and X² are independently selected from the groups consisting of: N, CH and -CR¹. A² and A³ are the same or different electron-withdrawing groups, and A² and A³ are not simultaneously the same as A¹. D¹, D² and D³ are electron-donating group. sp¹ to sp⁶ are independently selected from aromatic ring and heterocyclic ring. a, b and c are real numbers, and 0 < a ≦1, 0 ≦b ≦1, 0 ≦c ≦1, a+b+c=1. d, e, f, g, h and i are independently selected from 0, 1 and 2. The organic optoelectronic device of the present invention has adjustable energy gap, and can be a high-performance OPV or a high-detectivity OPD.

The present application is based on, and claims priority from, America provisional pat. application number US63/230,088, filed on 2021/August/06, and the disclosure of which is hereby incorporated by reference herein in its entirety.

### BACKGROUND OF THE INVENTION

### 1. Field of the Invention

The present invention relates to a conjugated polymer material applied to an organic optoelectronic device, and an organic optoelectronic device including the said conjugated polymer material.

### 2. Description of the Prior Art

In view of global warming, climate change has become a common challenge in the international communities. The Kyoto protocol proposed by the “United Nations Framework Convention on Climate Change (UNFCCC)” in 1997 which had entered into force in 2005 is aimed at reducing carbon dioxide emissions. In this regard, countries are focusing on the development of renewable energy to reduce the use of petrochemical fuels. As the sun provides far enough energy needs of people at present and for the future, renewable energy becomes a major concern for solar power generation, which has led to the use of organic optoelectronic devices for solar power generation as the primary development target.

In recent years, in addition to the application of organic photovoltaic (OPV), there is an emerging application field of organic photodetector (OPD).

In the application field of organic photovoltaic, the absorption wavelength of current organic photovoltaic is in the range of 320-900 nm. However, the absorption wavelength of organic photovoltaic is mainly concentrated in visible light at 400-700 nm, and it does not have the ability to absorb infrared light beyond 900 nm. It can be seen from this that some photons in sunlight which are still in the infrared region have not yet been used and converted into electric current or signals.

In the application field of organic photodetector, the light absorption range of organic materials can be adjusted, so it can effectively absorb the required wavelength bands, thereby achieving the effect of selective detection. The high extinction coefficient of organic materials can also effectively improve the detection efficiency. In recent years, the development of OPD has gradually developed from ultraviolet (UV) and visible light to near infrared (NIR). Therefore, the detected wavelength range of organic photodetector is not limited to 1000 nm. For example: the application wavelength of that needs to exceed 1000 nm in order to obtain better penetration and long-distance detection in intelligent driving and aerial photography machines application. The absorption wavelength of water is at 1350 nm, and the detector can be configured to detect the degree of moisture in food or medicine, so as to avoid accidental ingestion and affect the human body. Light with wavelengths above 1000 nm has deeper penetration of tissue for biological detection, which can improve the contrast of the image, and the organic optoelectronic device has better flexibility, which is conducive to the production of wearable health detectors. In addition, in order to reduce the interference value, the performance of the device needs to have the characteristics of low dark current and high detectability.

As mentioned above, it can be seen that the development of organic polymer materials with a wide absorption wavelength range (visible light region and near-infrared region) and absorption wavelength adjustment properties, which enable the absorption wavelength range to be adjusted according to the intended application field, is a very important issue at present. In addition, considering the future commercial application and environmental friendliness, organic polymer materials also need to have good solubility in non-halogen solvents.

### SUMMARY OF THE INVENTION

In view of this, one category of the present invention is to provide a conjugated polymer material to achieve a wide absorption wavelength range (visible light region and near-infrared region) and have absorption wavelength adjustment. According to a specific embodiment of the present invention, the conjugated polymer material comprises a structure of Formula I:

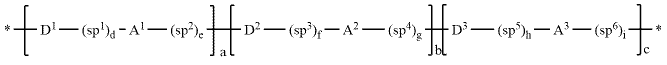

Wherein

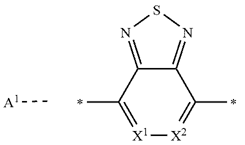

. Wherein, X¹ and X² are the same or different, and independently selected from the group consisting of: N, CH and -CR¹. R¹ is selected from the group consisting of: halogen, -C(O)R^{x1}, -CF₂R^{x1} and -CN, and R^{x1} is selected from the group consisting of: C1-C20 alkyl and C1-C20 haloalkyl. A² and A³ are the same or different electron-withdrawing groups. The electron-withdrawing groups comprise a polycyclic structure which comprises at least one five-member ring and at least one six-member ring, or a polycyclic structure which comprises at least two five-member ring. A² and A³ are not simultaneously the same as A¹. D¹, D² and D³ are the same or different electron-donating groups, and independently selected from the group consisting of: aromatic ring with or without substituent, fused ring with or without substituent, heterocyclic ring with or without substituent, and fused heterocyclic ring with or without substituent. sp¹ to sp⁶ are the same or different, and independently selected from the group consisting of: aromatic ring with or without substituent, and heterocyclic ring with or without substituent. a, b and c are real numbers, and 0 < a ≦ 1, 0 ≦ b ≦ 1, 0 ≦ c ≦ 1, a+b+c=1. d, e f, g, h and i are the same or different, and independently selected from 0, 1 and 2.

Wherein, b and c are not 0 at the same time.

Wherein, a is in a range from 0.1 to 0.9.

Wherein, D¹, D² and D³ respectively comprise the following structures of fused ring or fused heterocyclic ring having 11 to 24 members:

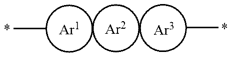

wherein Ar¹, Ar² and Ar³ are the same or different, and independently selected from the group consisting of: five-member aromatic ring with or without substituent, five-member heterocyclic ring with or without substituent, six-member aromatic ring with or without substituent, and six-member heterocyclic ring with or without substituent.

Wherein, D¹, D² and D³ are independently selected from the group consisting of the following structures:

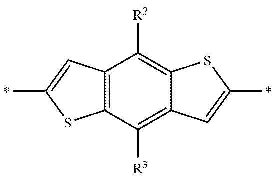

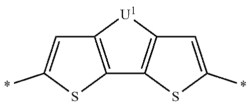

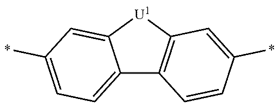

Wherein, R² and R³ are the same or different, and independently selected from the group consisting of: H, F, R^{x2}, -OR^{x2}, -SR^{x2}, -C(=O)R^{x2}, -C(=O)-OR^{x2} and -S(=O)₂R^{x2}. R^{x2} is selected from the group consisting of: C1-C30 alkyl with or without substituent, and the substituent is independently selected from the group consisting of: O, S, aromatic ring and heterocyclic ring. U¹ is selected from the group consisting of: CR⁴R⁵, SiR⁴R⁵, GeR⁴R⁵, NR⁴ and C=O. R⁴ and R⁵ are the same or different, and independently selected from the group consisting of: C1-C30 alkyl with or without substituent, and the substituent is independently selected from the group consisting of: O, S, aromatic ring and heterocyclic ring.

Wherein, A² and A³ are the electron-withdrawing groups with or without substituent, and the structure of the electron-withdrawing groups respectively comprise at least one of the group consisting of: S, N, Si, Se, C=O, CN and SO₂.

Wherein, A² and A³ are independently selected from the following structures and the mirror phase structures thereof:

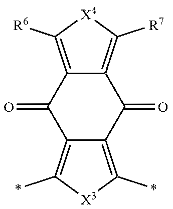

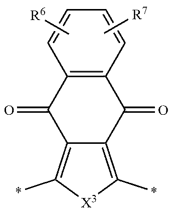

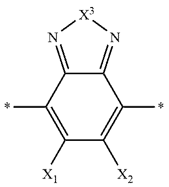

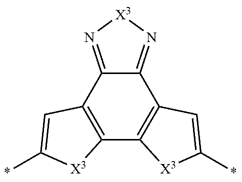

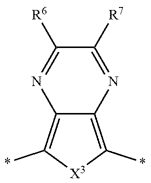

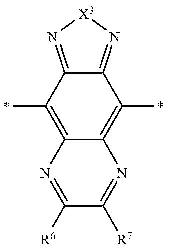

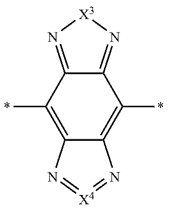

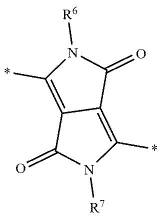

Wherein, X³ is selected from the group consisting of: S, Se, O, NR^{x3} and R^{x3}. R^{x3} is selected from the group consisting of: C1-C30 alkyl with or without substituent, and the substituent is independently selected from the group consisting of: O, S, aromatic ring and heterocyclic ring. X⁴ is selected from the group consisting of: S, Se and O. R⁶ and R⁷ are the same or different, and independently selected from the group consisting of: H, F, R^{x4}, -OR^{x4}, -SR^{x4}, -C(=O)R^{x4}, -C(=O)-OR^{x4} and -S(=O)₂R^{x4}. R^{x4} is selected from the group consisting of: C1-C30 alkyl with or without substituent, and the substituent is independently selected from the group consisting of: O, S, aromatic ring and heterocyclic ring.

Wherein, A² and A³ are independently selected from the following structures and the mirror phase structures thereof:

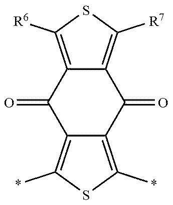

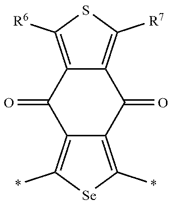

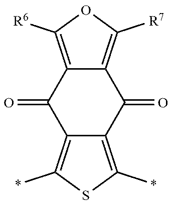

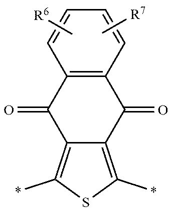

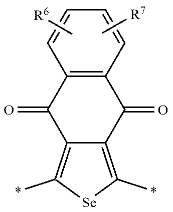

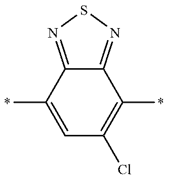

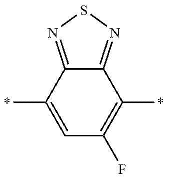

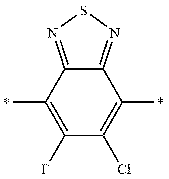

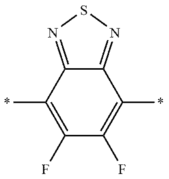

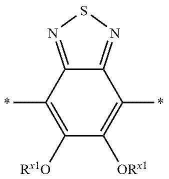

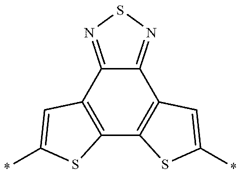

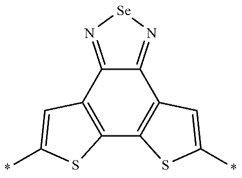

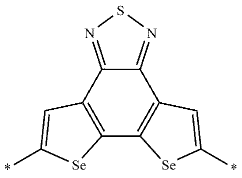

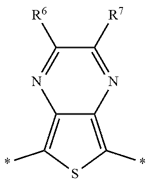

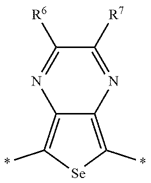

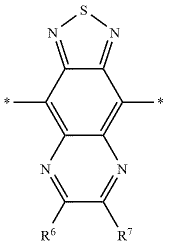

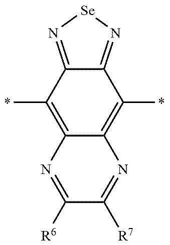

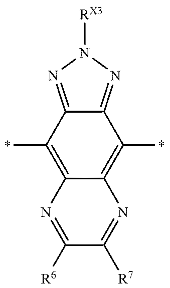

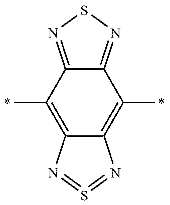

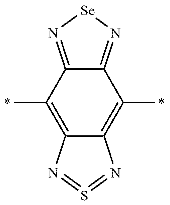

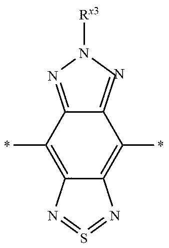

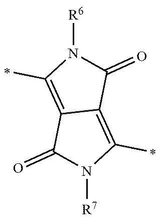

Wherein, R^{x1}, and R⁶, R⁷ and R^{x3} are as defined above.

Wherein, sp¹ to sp⁶ are independently selected from the group consisting of:

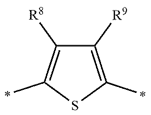

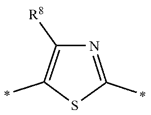

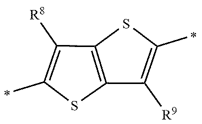

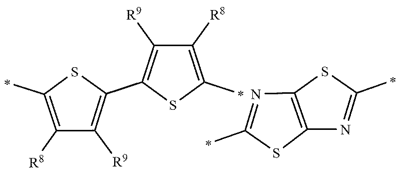

Wherein, R⁸ and R⁹ are the same or different, and independently selected from the group consisting of: H, F, R^{x5}, -OR^{x5}, -SR^{x5}, -C(=O)R^{x5}, -C(=O)-OR^{x5} and -S(=O)₂R^{x5}. R^{x5} is selected from the group consisting of: C1-C30 alkyl with or without substituent, and the substituent is independently selected from the group consisting of: O, S, aromatic ring and heterocyclic ring.

Another category of the present invention is to provide an organic optoelectronic device comprises a first electrode including a transparent electrode, a first carrier transport layer, an active layer which at least comprises the aforementioned conjugated polymer material, a second carrier transport layer and a second electrode. Wherein, the first carrier transport layer is disposed between the first electrode and the active layer, the active layer is disposed between the first carrier transport layer and the second carrier transport layer, and the second carrier transport layer is disposed between the active layer and the second electrode.

Wherein, the first carrier transport layer is one of the electron transporting layer and the hole transporting layer, and the second carrier transport layer is the other.

Compared with the prior art, the organic optoelectronic device fabricated by using the conjugated polymer material of the present invention has a wide absorption wavelength range. In addition, the organic optoelectronic device fabricated by using the conjugated polymer material of the present invention can adjust its energy gap by structure tuning to adjust its absorption wavelength range, and then can be customized according to its intended application field. In other words, the organic optoelectronic device fabricated by using the conjugated polymer material of the present invention has good absorption coefficient in the infrared region, and has the characteristics of low dark current and high detectivity. In addition, the conjugated polymer material of the present invention has good solubility in non-halogen solvents, and has better commercial and environment-friendly applications.

### BRIEF DESCRIPTION OF THE APPENDED DRAWINGS

Some of the embodiments will be described in detail, with reference to the following figures, wherein like designations denote like members, wherein:

FIG. 1 shows a schematic structural diagram of one embodiment of an organic optoelectronic device of the present invention.

FIG. 2 shows an absorption spectra of an embodiments P1 of the conjugated polymer material of the present invention in solution state and thin film state.

FIG. 3 shows an absorption spectra of an embodiments P2 of the conjugated polymer material of the present invention in solution state and thin film state.

FIG. 4 shows an absorption spectra of an embodiments P3 of the conjugated polymer material of the present invention in solution state and thin film state.

FIG. 5 shows an absorption spectra of an embodiments P4 of the conjugated polymer material of the present invention in solution state and thin film state.

FIG. 6 shows an absorption spectra of an embodiments P5 of the conjugated polymer material of the present invention in solution state and thin film state.

FIG. 7 shows an absorption spectra of an embodiments P6 of the conjugated polymer material of the present invention in solution state and thin film state.

FIG. 8 shows an absorption spectra of an embodiments P7 of the conjugated polymer material of the present invention in solution state and thin film state.

FIG. 9 shows an absorption spectra of an embodiments P8 of the conjugated polymer material of the present invention in solution state and thin film state.

FIG. 10 shows a schematic energy level diagram of eight embodiments P1 to P8 of the conjugated polymer materials of the present invention.

FIG. 11 shows a J-V diagram of an embodiment P1 of the organic photovoltaic of the present invention.

FIG. 12 shows a J-V diagram of an embodiment P2 of the organic photovoltaic of the present invention.

FIG. 13 shows test results of the external quantum efficiency (EQE) of the embodiment P1 of the organic photovoltaic of the present invention.

FIG. 14 shows a PCE error bar diagram of the embodiments P1 and P2 of the organic photovoltaics of the present invention.

FIG. 15 shows a J-V diagram of an embodiment P4 of the organic photodetector of the present invention (the active layer thickness is 100 nm).

FIG. 16 shows a J-V diagram of the embodiment P4 of the organic photodetector of the present invention (the active layer thickness is 450 nm).

FIG. 17 shows test results of the external quantum efficiency (EQE) of the embodiment P4 of the organic photodetector of the present invention (the active layer thickness is 100 nm).

FIG. 18 shows test results of the external quantum efficiency (EQE) of the embodiment P4 of the organic photodetector of the present invention (the active layer thickness is 450 nm).

FIG. 19 shows a J-V diagram of an embodiment P7 of the organic photodetector of the present invention.

FIG. 20 shows test results of the external quantum efficiency (EQE) of the embodiment P7 of the organic photodetector of the present invention.

FIG. 21 shows a J-V diagram of an embodiment P8 of the organic photodetector of the present invention.

FIG. 22 shows test results of the external quantum efficiency (EQE) of the embodiment P8 of the organic photodetector of the present invention.

### DETAILED DESCRIPTION OF THE INVENTION

In order to make the advantages, spirit and features of the present invention easier and clearer, it will be detailed and discussed in the following with reference to the embodiments and the accompanying drawings. It is worth noting that the specific embodiments are merely representatives of the embodiments of the present invention, but it can be implemented in many different forms and is not limited to the embodiments described in this specification. Rather, these embodiments are provided so that this disclosure will be thorough and complete.

The terminology used in the various embodiments disclosed in the present invention is only for the purpose of describing specific embodiments, and is not intended to limit the various embodiments disclosed in the present invention. As used herein, singular forms also include plural forms unless the context clearly indicates otherwise. Unless otherwise defined, all terms (including technical and scientific terms) used in this specification have the same meanings as commonly understood by one of ordinary skill in the art to which the various embodiments disclosed herein belong. The above terms (such as those defined in commonly used dictionaries) will be interpreted as having the same meaning as the contextual meaning in the same technical field, and will not be interpreted as having an idealized or overly formal meaning, unless explicitly defined in the various embodiments disclosed herein.

In the description of this specification, the description of the reference terms “an embodiment”, “a specific embodiment” and the like means that specific features, structures, materials, or characteristics described in connection with the embodiment are included in at least one embodiment of the present invention. In this specification, the schematic expressions of the above terms do not necessarily refer to the same embodiment. Furthermore, the particular features, structures, materials, or characteristics described may be combined in any suitable manner in any one or more embodiments.

### Definition

As used herein, “donor” material refers to a semiconductor material, such as an organic semiconductor material, having holes as a primary current or charge carrier. In some embodiments, when a P-type semiconductor material is deposited on a substrate, it can provide the hole mobility greater than about 10⁻⁵ cm²/Vs. In the case of field effect devices, current on/off ratio of the P-type semiconductor material exhibits more than about 10.

As used herein, “acceptor” material refers to the semiconductor material, such as the organic semiconductor material, having electrons as the primary current or the charge carrier. In some embodiments, when a N-type semiconductor material is deposited on a substrate, it can provide the electron mobility greater than about 10⁻⁵ cm²/Vs. In the case of field effect devices, current on/off ratio of the N-type semiconductor material exhibits more than about 10.

As used herein, “mobility” refers to a speed rate of the charge carrier moving through the material under the influence of an electric field. The charge carrier is the hole (positive charge) in the P-type semiconductor material and the electron (negative charge) in the N-type semiconductor material. This parameter depends on architecture of device and can be measured by field effect component or space charge limiting current.

The compound as used herein is considered as “environmentally stable” or “stabilized under ambient conditions” and refers to that when a transistor incorporates the compound as semiconductor material, the carrier mobility is shown to remain as its initial value after the compound has been exposed to ambient conditions such as air, ambient temperature and humidity for a period of time. For example, a compound may be considered to be environmentally stable if the change in carrier mobility of a transistor incorporating the compound is less than 20% or 10% of the initial value after being exposed to the environmental conditions including air, humidity and temperature for 3, 5 or 10 days.

Fill factor (FF) used herein refers to the ratio of the actual maximum available power (P ₘ or V ₘₚ ^{∗} J ₘₚ) to the theoretical (non-actually available) power (J _{sc} ^{∗} V _{oc}). Therefore, the fill factor can be determined by the following formula:

$$\text{FF} = \left({\text{V}}_{\text{mp}} ∗ {\text{J}}_{\text{mp}}\right) / \left({\text{V}}_{\text{oc}} ∗ {\text{J}}_{\text{sc}}\right)$$

Wherein, the J ₘₚ and V ₘₚ respectively represent the current density and voltage at the maximum power point which is obtained by varying the resistance in the circuit to get the maximum value of J * V. J _{sc} and V_{oc} represent short circuit current and open circuit voltage, respectively. The fill factor is a key parameter for evaluating solar cells. The fill factor of commercial solar cells is typically greater than about 60%. The open circuit voltage (V _{oc}) used herein is the potential difference between the anode and the cathode of the component without connecting the external load.

The power conversion efficiency (PCE) of solar cells used herein refers to the conversion percentage of power from the incident light to the electricity power. The power conversion efficiency (PCE) of solar cells can be calculated by dividing the maximum power point (P ₘ) by the incident light irradiance (E; W/m²) under the standard test conditions (STC) and the surface area (Ac; m²) of the solar cells. STC generally refers to the conditions of temperature at 25° C., irradiance of 1000 W/m², and air mass (AM) 1.5 spectrum.

The external quantum efficiency (EQE) as used herein is the spectral response Amp/Watt unit. Convert Amp to the number of electrons per unit time (electron/sec) and Watt to convert the number of photons per unit time (Photons/sec), and calculate the quantum efficiency by the above formula. Generally speaking, quantum efficiency (QE) refers to external quantum efficiency (EQE), also known as incident photon-electron conversion efficiency (IPCE).

Dark current (J _{d}) as used herein also known as no-illumination current, refers to the current flows in an optoelectronic device in the absence of light irradiation.

The responsibility (R) and the detectivity (D) as used herein are based on measuring the dark current and external quantum efficiency (EQE) of the organic photodetector, and are calculated by the following formula:

$$R \left(λ\right) = E Q E \frac{λ q}{h c} D = \frac{R}{\sqrt{2 q {\text{J}}_{\text{D}}}}$$

Wherein, λ is the wavelength, q is the elementary charge (1.602×10⁻¹⁹ Coulombs), h is Planck’s constant (6.626×10⁻³⁴ m² kg/s), and c is the speed of light (3×10⁸ m /sec), J _{D} is the dark current density.

The member (e.g., a thin film layer) as used herein can be considered as “photoactive” if it contains one or more compounds capable of absorbing photons to generate excitons for producing photocurrents.

As used herein, “solution proceeding” refers to a process in which a compound (e.g., a polymer), material, or composition can be used in a solution state, such as spin coating, printing (e.g., inkjet printing, gravure printing, and lithography printing), spray coating, slit coating, drop casting, dip coating, and blade coating.

As used herein, “annealing” refers to a post-deposition thermal treatment to a semi-crystalline polymer film for certain duration in the environment or under decompressed or pressurized environment. “Annealing temperature” refers to the temperature at which the polymer film or the mixed film of the polymer and other molecules can perform small-scale molecular movement and rearrangement during the annealing process. Without limitation by any particular theory, it is believed that annealing can lead to an increase in crystallinity in the polymer film, enhance the carrier mobility of the polymer film or a mixed film formed by the polymer and other molecules, and the molecules are arranged alternately to achieve the effect of independent transporting paths of effective electrons and holes.

In an embodiment, the conjugated polymer material of the present invention comprises a structure of Formula I:

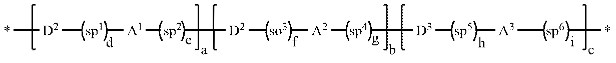

Wherein

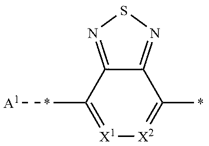

. Wherein, X¹ and X² are the same or different, and independently selected from the group consisting of: N, CH and -CR¹. R¹ is selected from the group consisting of: halogen, -C(O)R^{x1}, -CF₂R^{x1} and -CN, and R^{x1} is selected from the group consisting of: C1-C20 alkyl and C1-C20 haloalkyl. A² and A³ are the same or different electron-withdrawing groups. The electron-withdrawing groups comprise a polycyclic structure which comprises at least one five-member ring and at least one six-member ring, or a polycyclic structure which comprises at least two five-member ring. A² and A³ are not simultaneously the same as A¹. D¹, D² and D³ are the same or different electron-donating groups, and independently selected from the group consisting of: aromatic ring with or without substituent, fused ring with or without substituent, heterocyclic ring with or without substituent, and fused heterocyclic ring with or without substituent. sp¹ to sp⁶ are the same or different, and independently selected from the group consisting of: aromatic ring with or without substituent, and heterocyclic ring with or without substituent. a, b and c are real numbers, and 0 < a ≦ 1, 0 ≦ b ≦ 1, 0 ≦ c ≦ 1, a+b+c=1. d, e f, g, h and i are the same or different, and independently selected from 0, 1 and 2.

Wherein, the electron-withdrawing group is a group or atom with stronger electron-withdrawing ability than hydrogen, that is, it has the electron-withdrawing inductive effect. The electron-donating group is a group or atom with stronger electron-donating ability than hydrogen, that is, it has the electron-donating inductive effect. The inductive effect is the effect that the bonding electronic cloud moves in a certain direction on the atomic bond due to the different polarities (electronegativity) of the atoms or groups in the molecule. The electronic cloud prefers to move towards the group or atom with high electronegativity.

Here, it should be noted that ^{“}*^{”} or “^{∗}” in the structure listed in this specification represents the position where the structure can be bonded, but it is not limited thereto.

In practice, D¹, D² and D³ respectively comprise the following structures of fused ring or fused heterocyclic ring having 11 to 24 members:

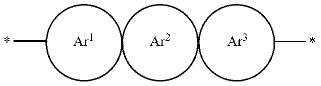

wherein Ar¹, Ar² and Ar³ are the same or different, and independently selected from the group consisting of: five-member aromatic ring with or without substituent, five-member heterocyclic ring with or without substituent, six-member aromatic ring with or without substituent, and six-member heterocyclic ring with or without substituent.

In practice, D¹, D² and D³ are independently selected from the group consisting of the following structures:

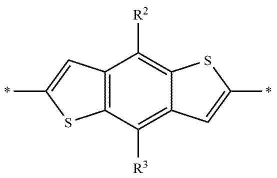

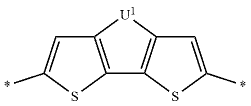

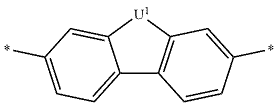

Wherein, R² and R³ are the same or different, and independently selected from the group consisting of: H, F, R^{x2}, -OR^{x2}, -SR^{x2}, -C(=O)R^{x2}, -C(=O)-OR^{x2} and -S(=O)₂R^{x2}. R^{x2} is selected from the group consisting of: C1-C30 alkyl with or without substituent, and the substituent is independently selected from the group consisting of: O, S, aromatic ring and heterocyclic ring. U¹ is selected from the group consisting of: CR⁴R⁵, SiR⁴R⁵, GeR⁴R⁵, NR⁴ and C=O. R⁴ and R⁵ are the same or different, and independently selected from the group consisting of: C1-C30 alkyl with or without substituent, and the substituent is independently selected from the group consisting of: O, S, aromatic ring and heterocyclic ring.

In practice, A² and A³ are the electron-withdrawing groups with or without substituent, and the structure of the electron-withdrawing groups respectively comprise at least one of the group consisting of: S, N, Si, Se, C=O, CN and SO₂.

In practice, A² and A³ are independently selected from the following structures and the mirror phase structures thereof:

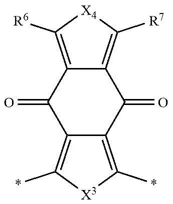

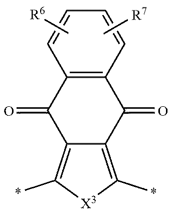

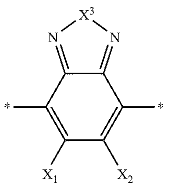

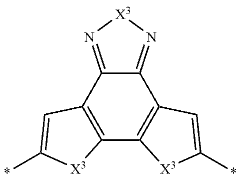

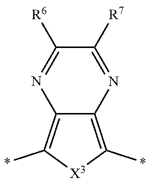

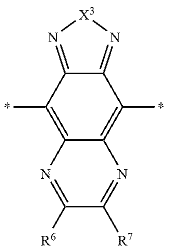

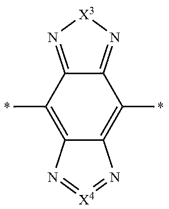

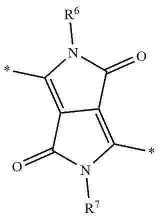

Wherein, X³ is selected from the group consisting of: S, Se, O, NR^{x3} and R^{x3}. R^{x3} is selected from the group consisting of: C1-C30 alkyl with or without substituent, and the substituent is independently selected from the group consisting of: O, S, aromatic ring and heterocyclic ring. X⁴ is selected from the group consisting of: S, Se and O. R⁶ and R⁷ are the same or different, and independently selected from the group consisting of: H, F, R^{x4}, -OR^{x4}, -SR^{x4}, -C(=O)R^{x4}, -C(=O)-OR^{x4} and -S(=O)₂R^{x4}. R^{x4} is selected from the group consisting of: C1-C30 alkyl with or without substituent, and the substituent is independently selected from the group consisting of: O, S, aromatic ring and heterocyclic ring.

Further, A² and A³ are independently selected from the following structures and the mirror phase structures thereof:

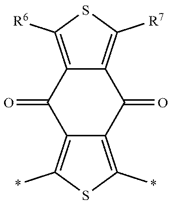

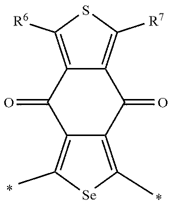

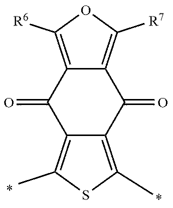

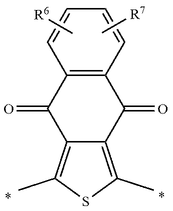

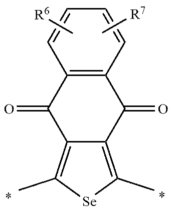

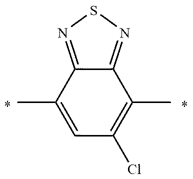

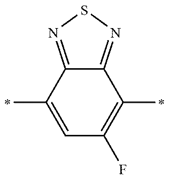

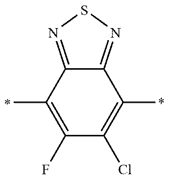

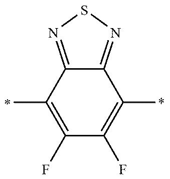

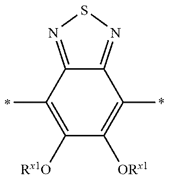

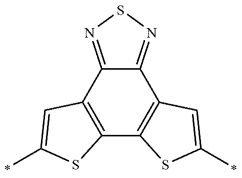

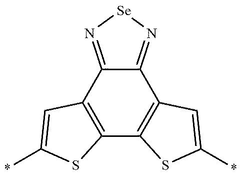

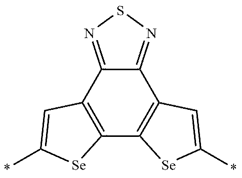

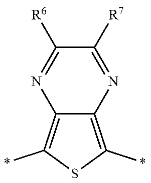

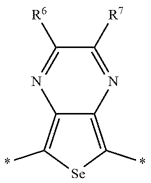

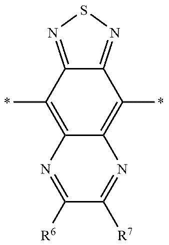

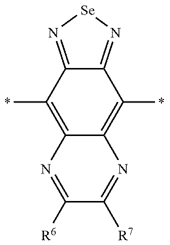

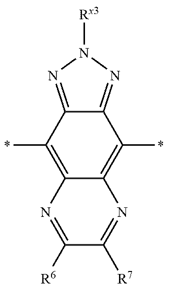

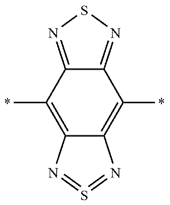

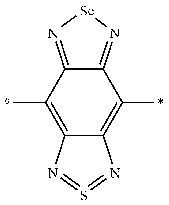

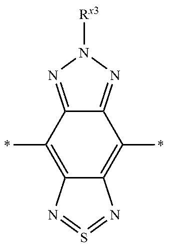

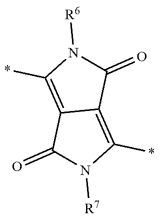

Wherein, R^{X1}, and R⁶, R⁷ and R^{x3} are as defined above.

In practice, sp¹ to sp⁶ are independently selected from the group consisting of:

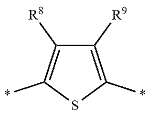

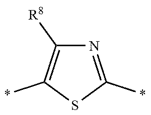

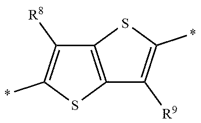

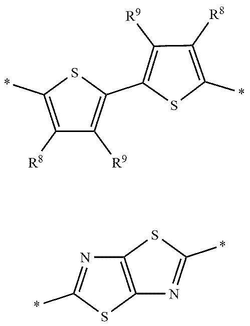

Wherein, R⁸ and R⁹ are the same or different, and independently selected from the group consisting of: H, F, R^{x5}, -OR^{x5}, -SR^{x5}, -C(=O)R^{x5},-C(=O)-OR^{x5} and -S(=O)₂R^{x5}. R^{x5} is selected from the group consisting of: C1-C30 alkyl with or without substituent, and the substituent is independently selected from the group consisting of: O, S, aromatic ring and heterocyclic ring.

In practice, the conjugated polymer material of the present invention comprises the following structures:

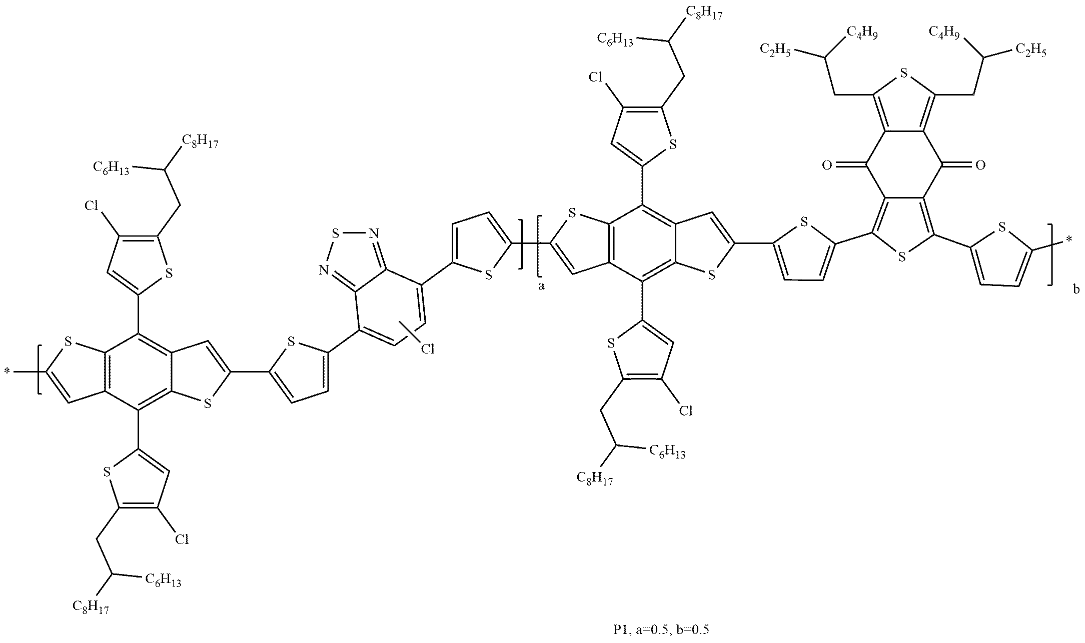

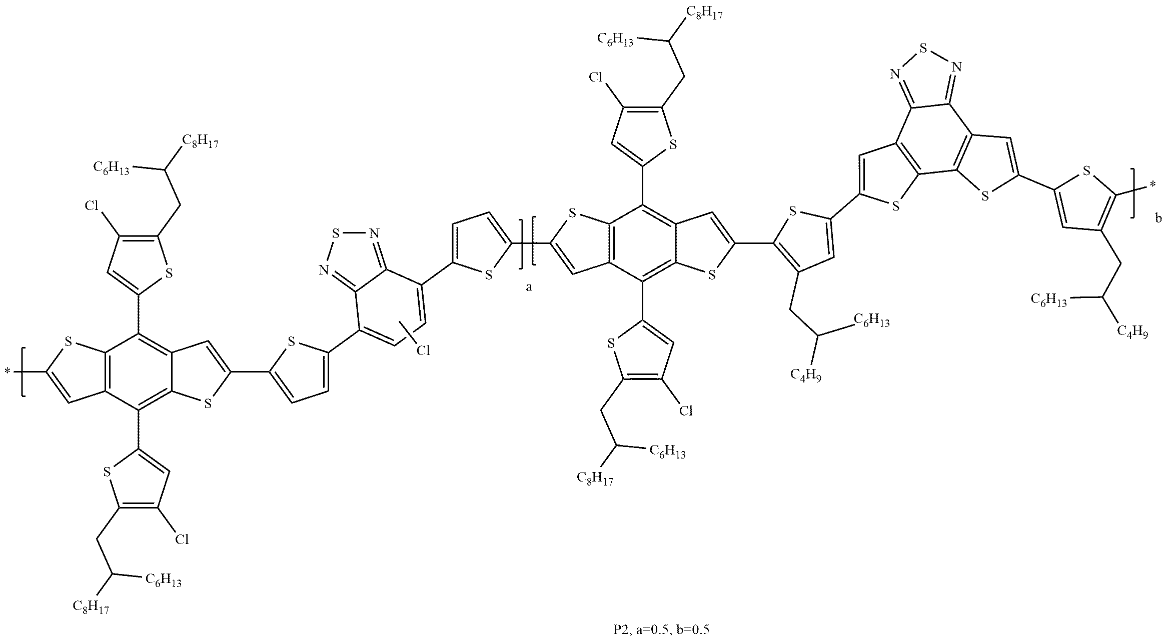

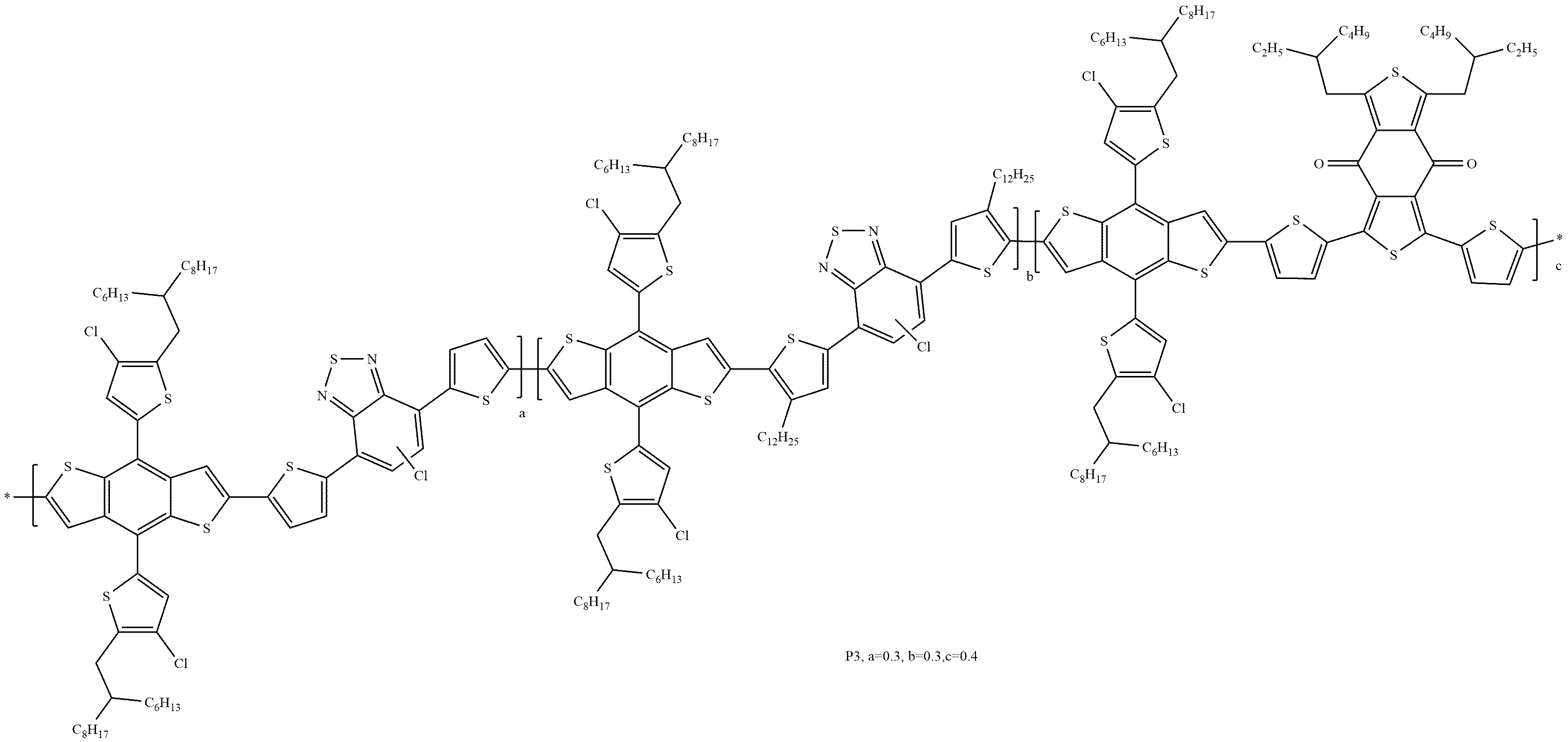

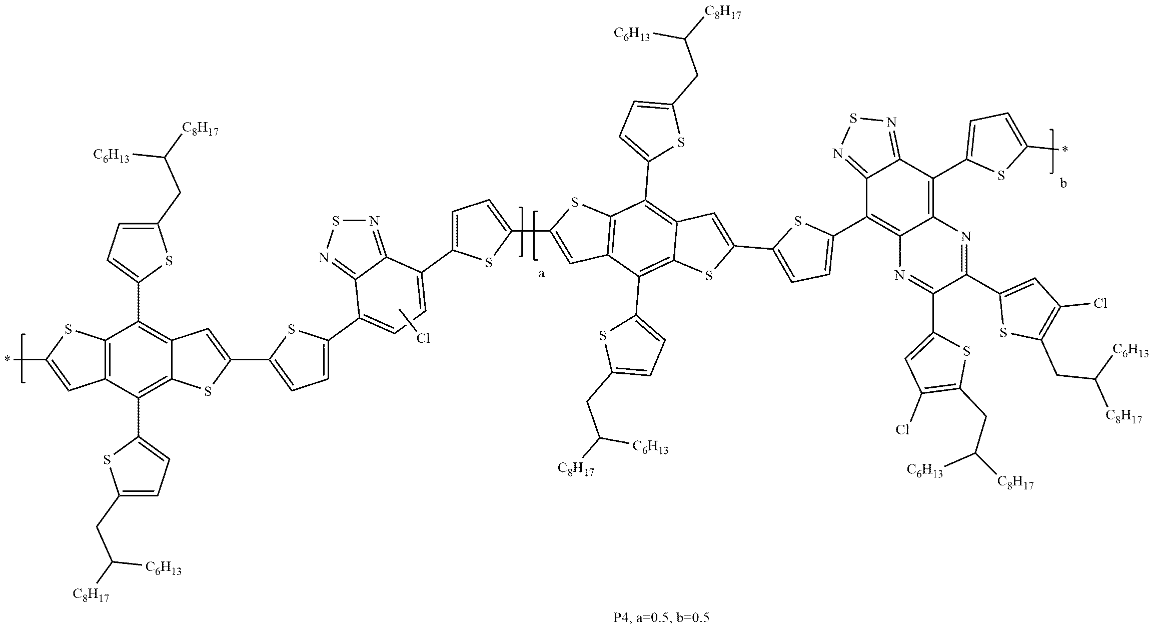

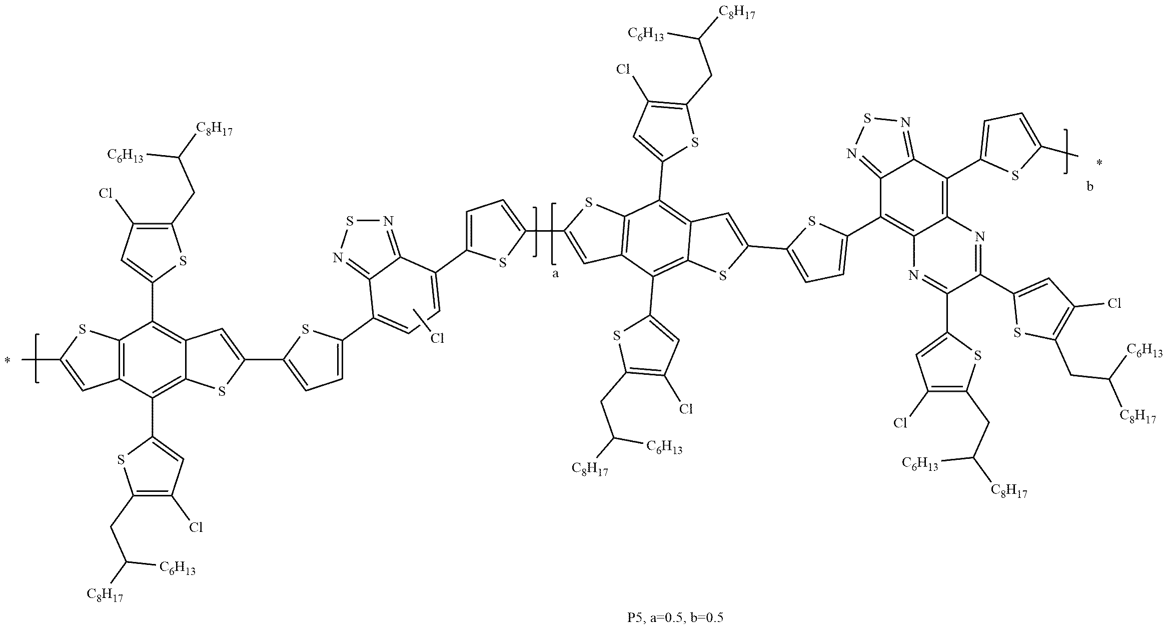

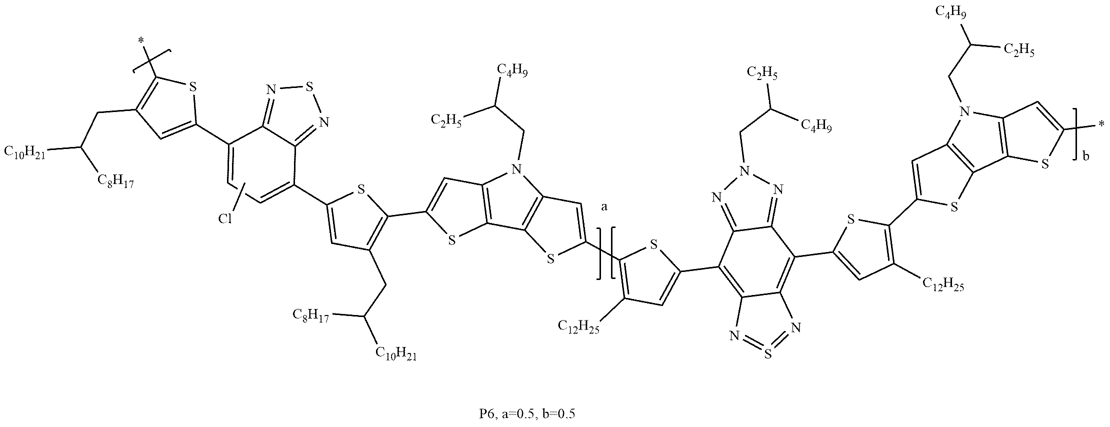

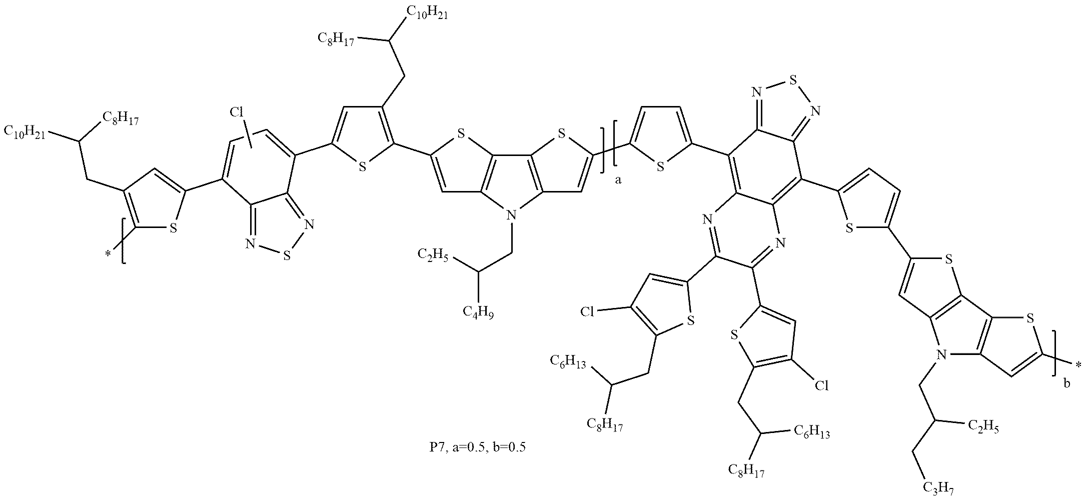

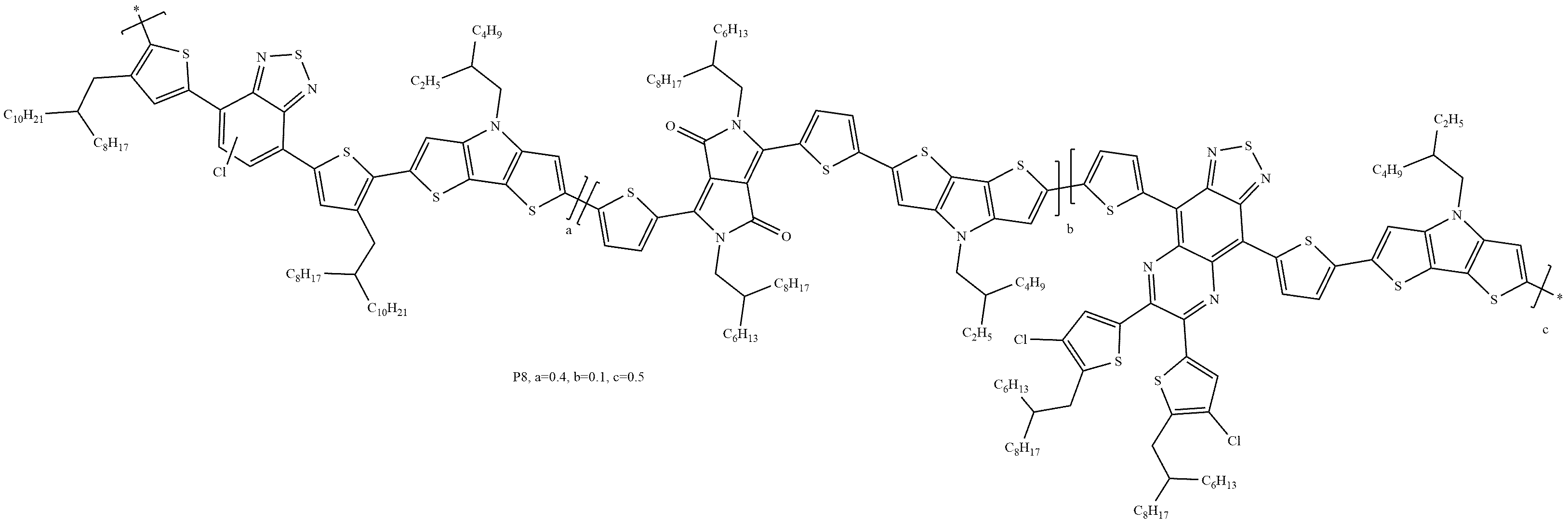

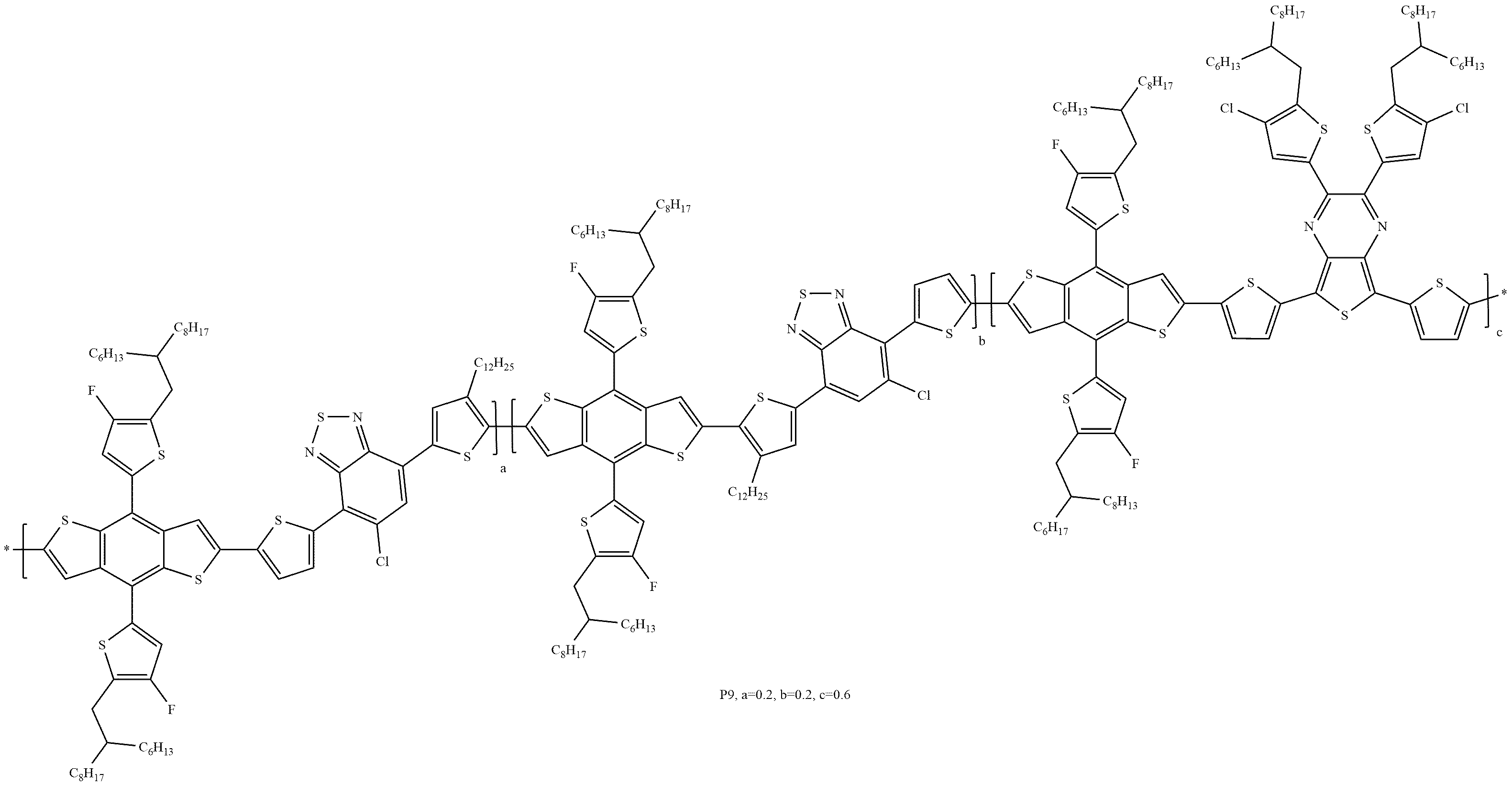

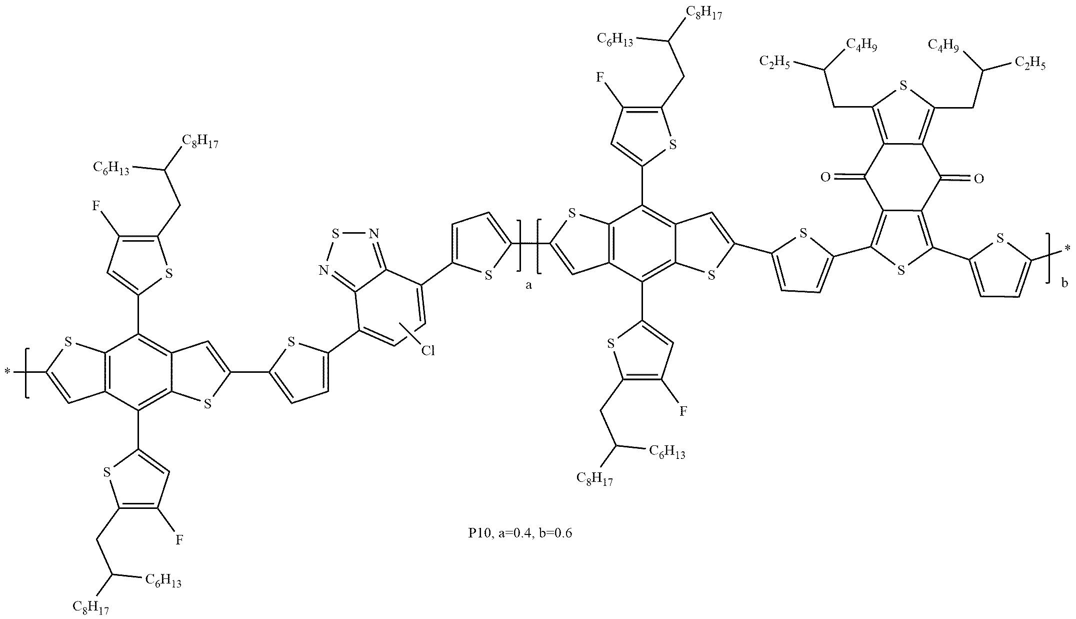

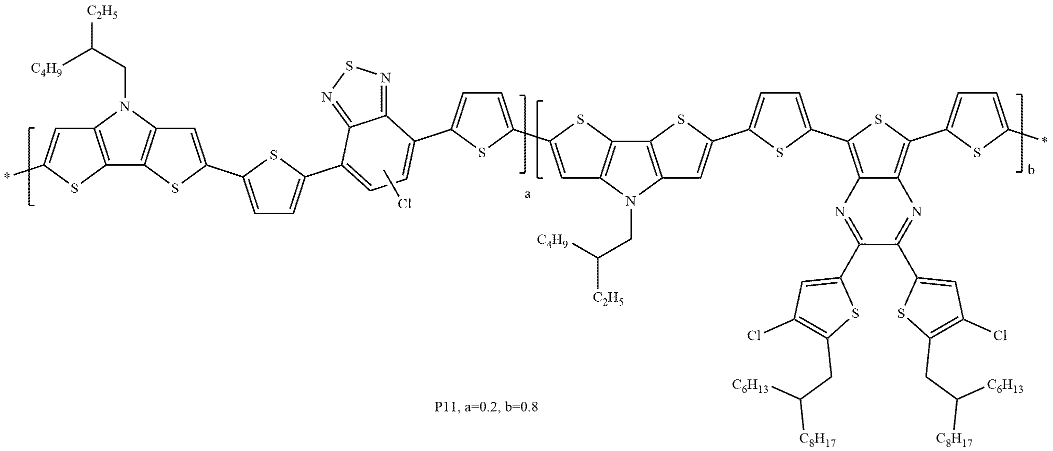

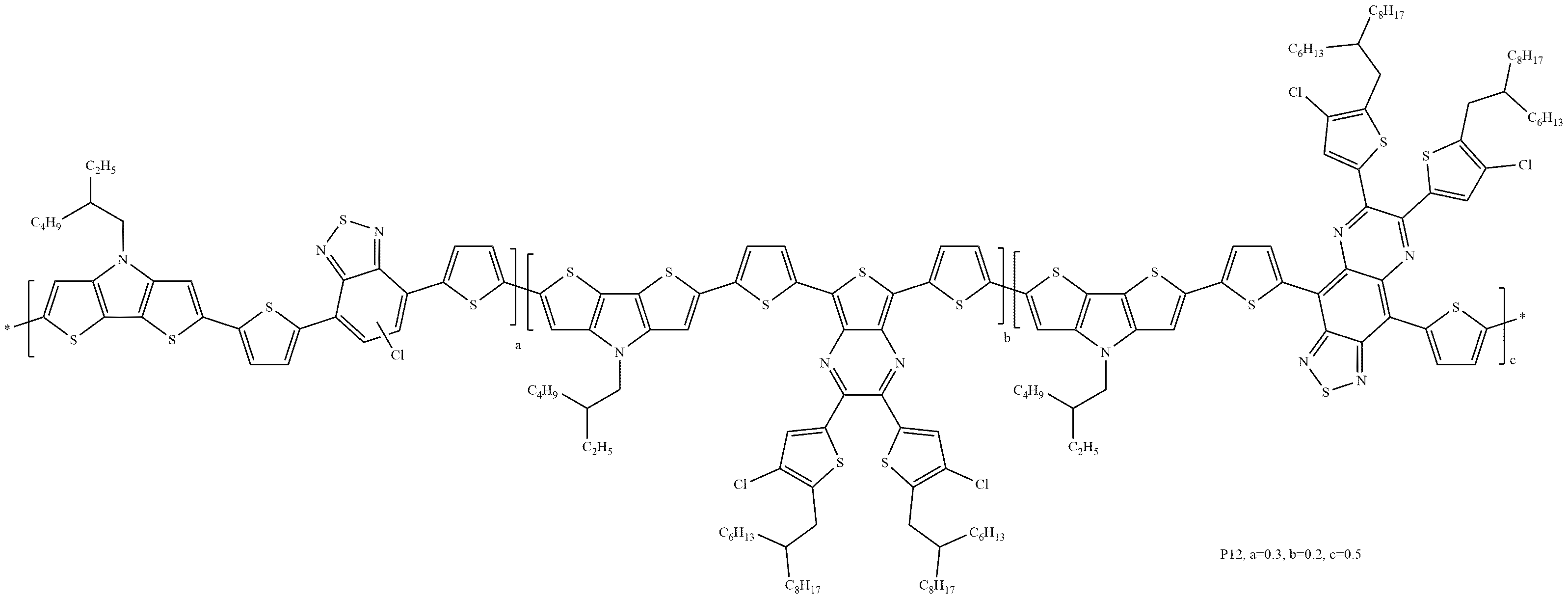

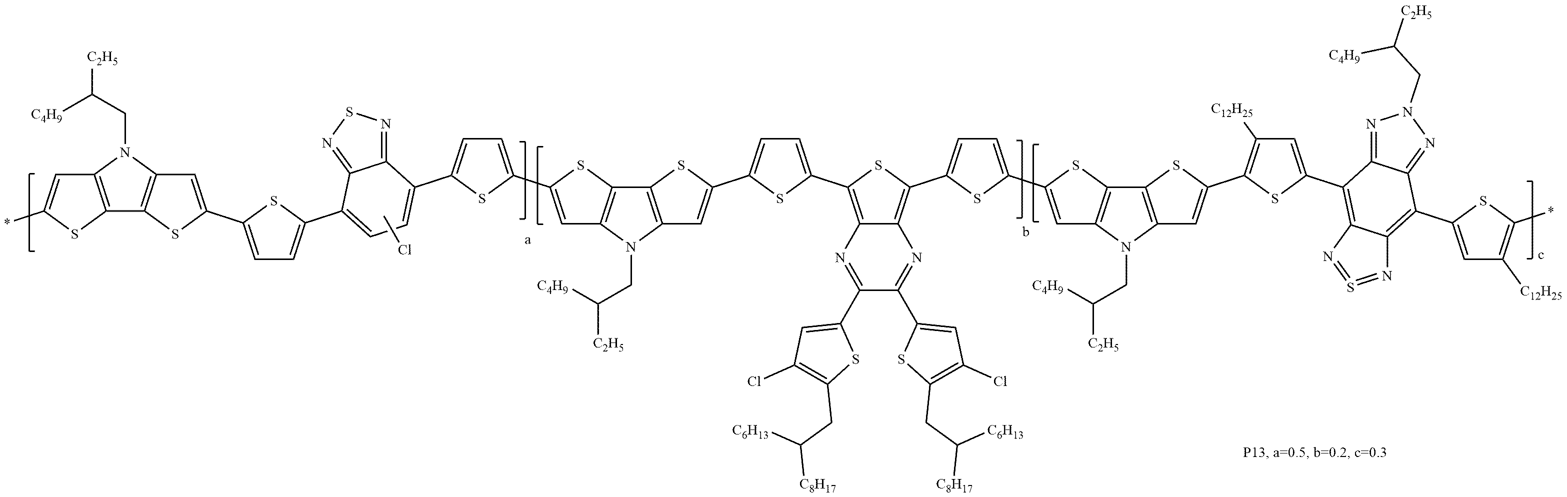

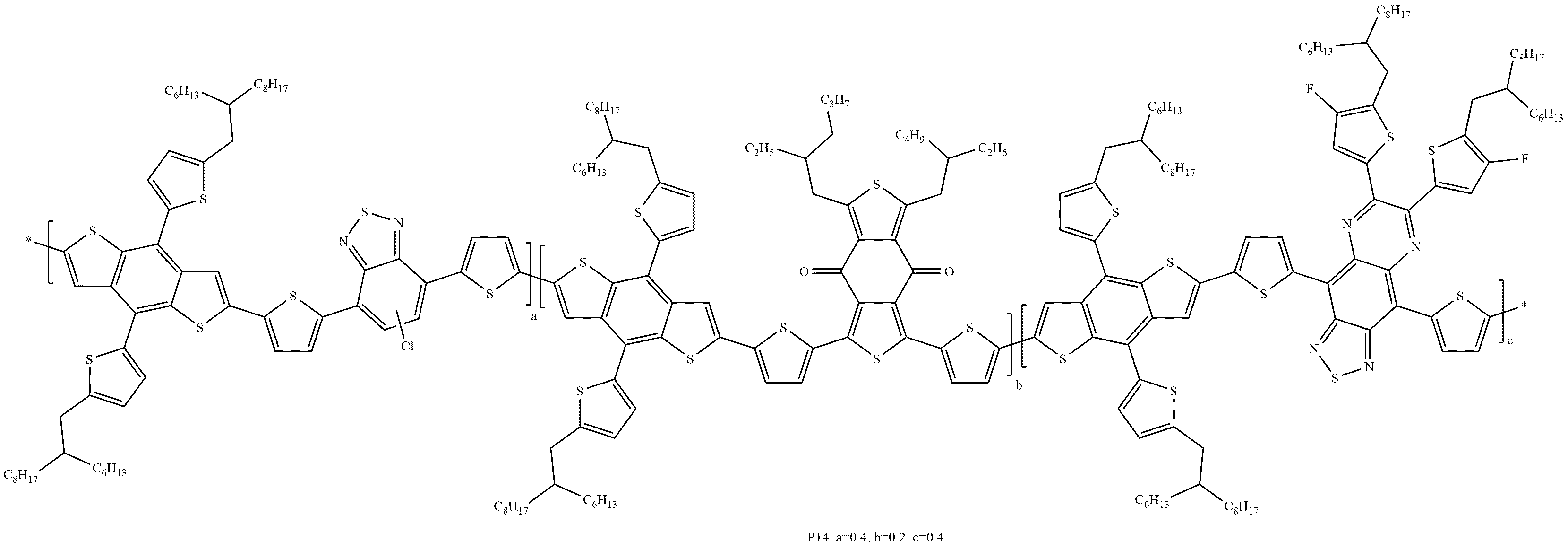

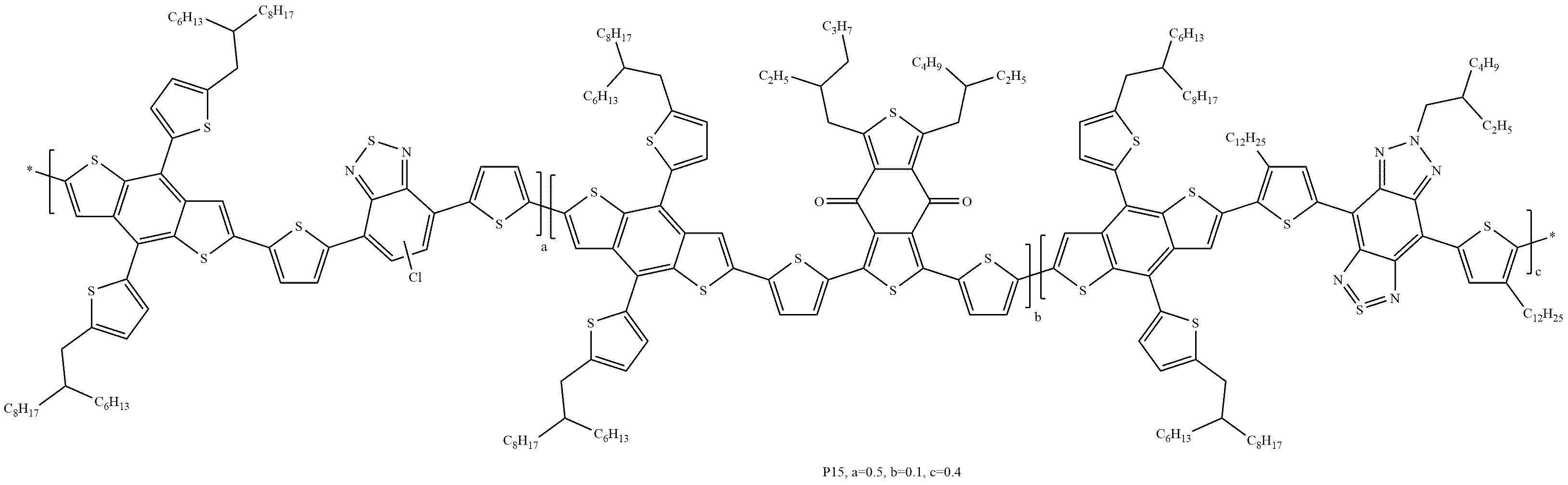

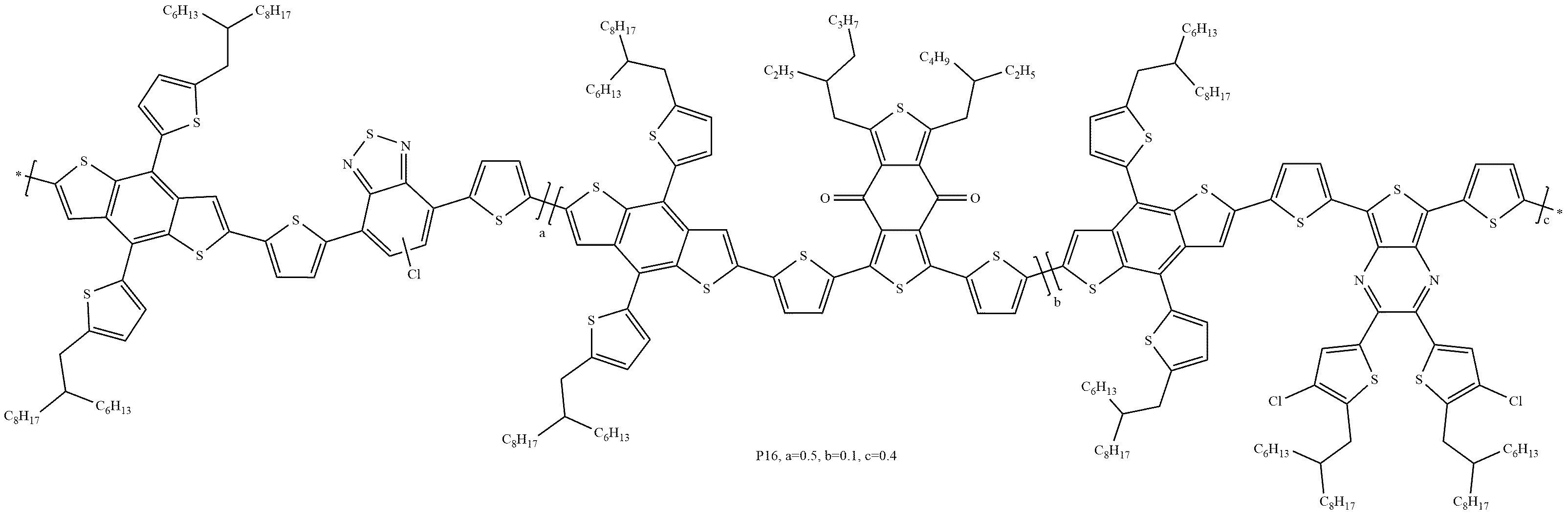

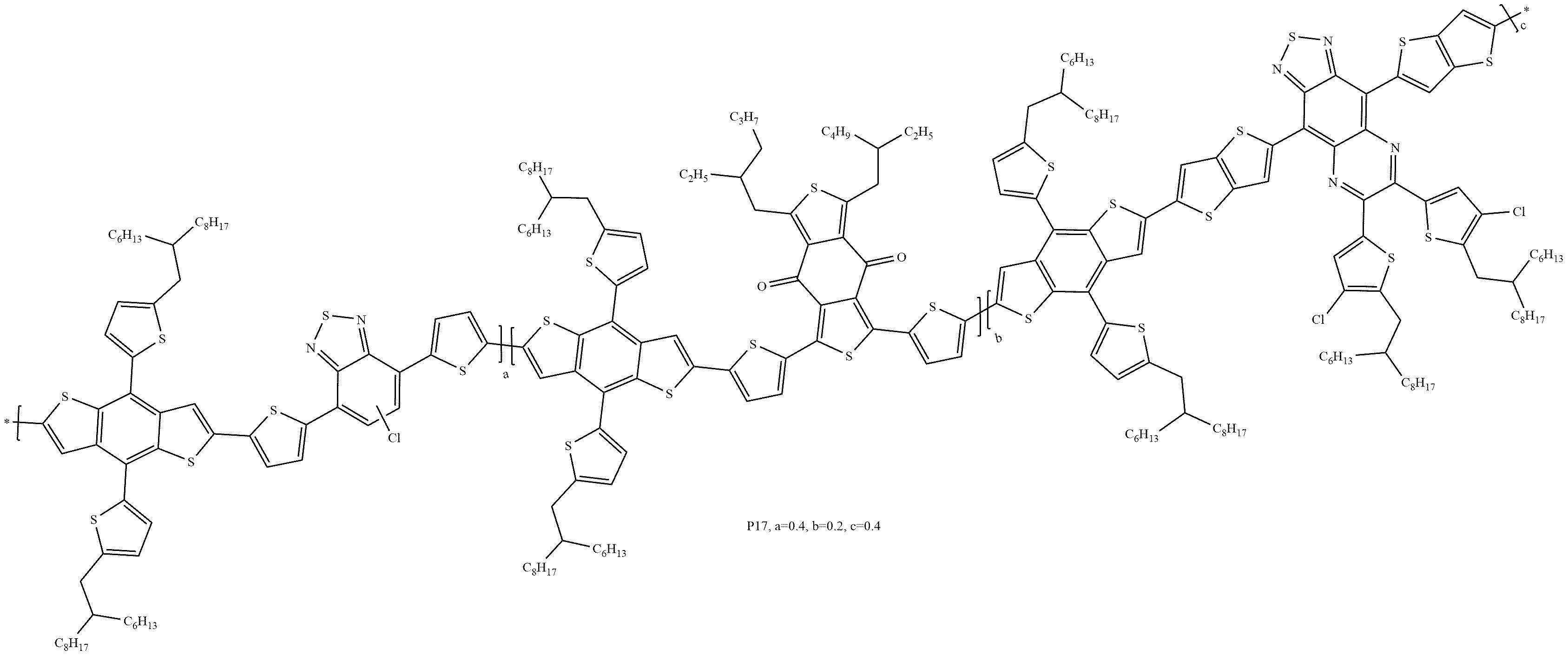

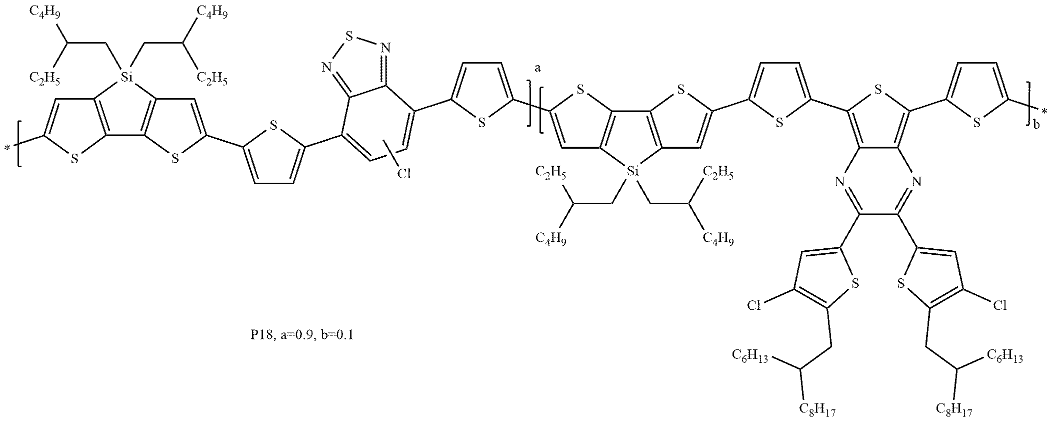

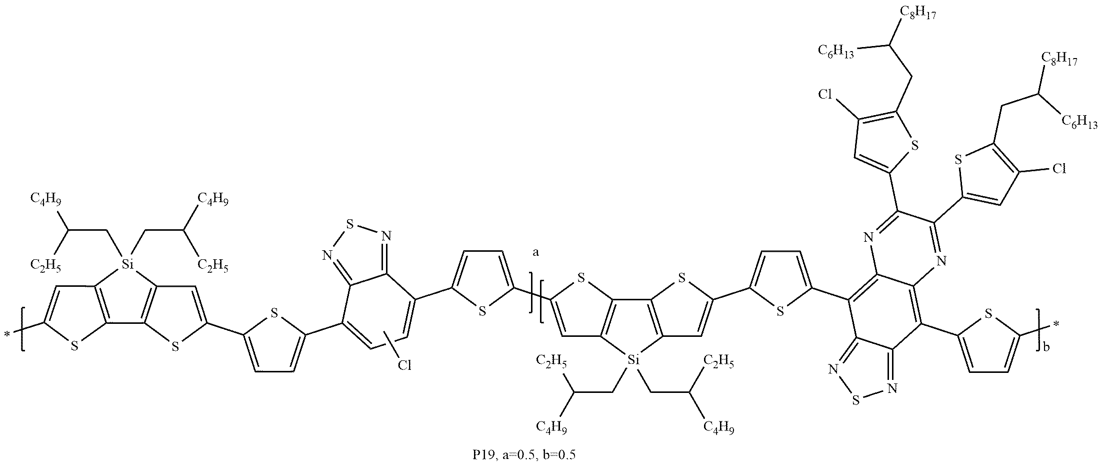

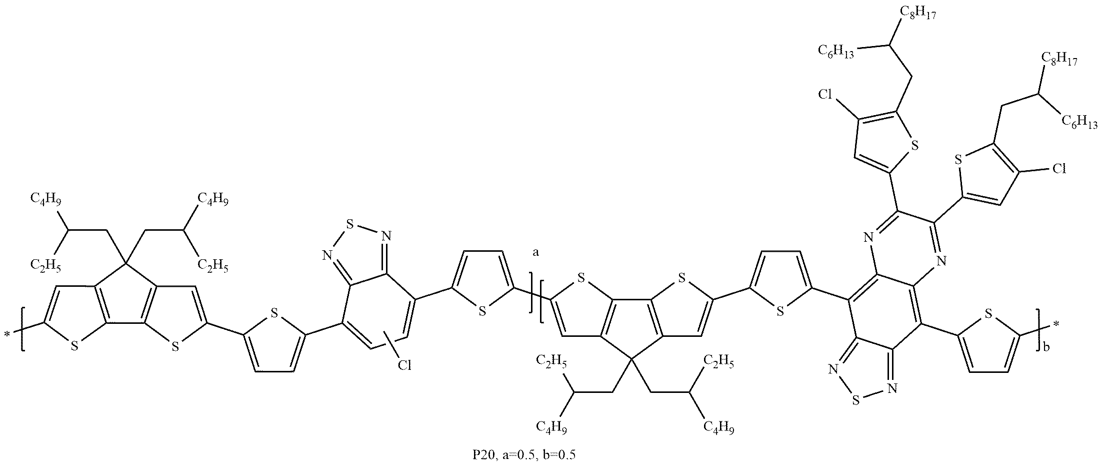

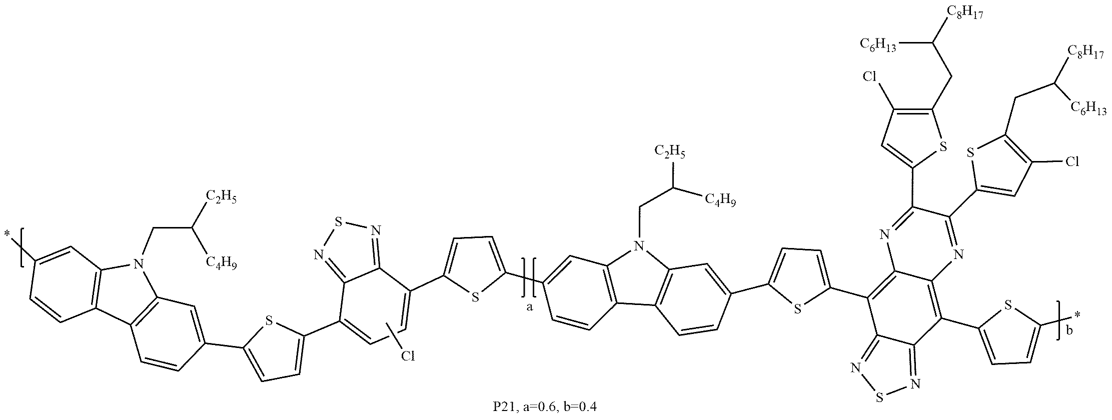

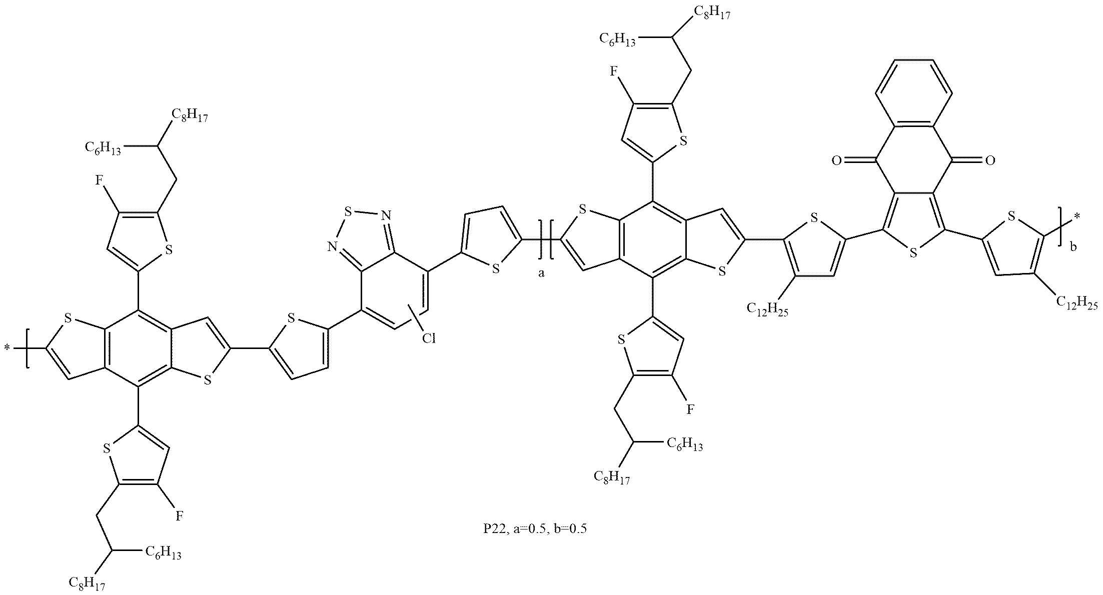

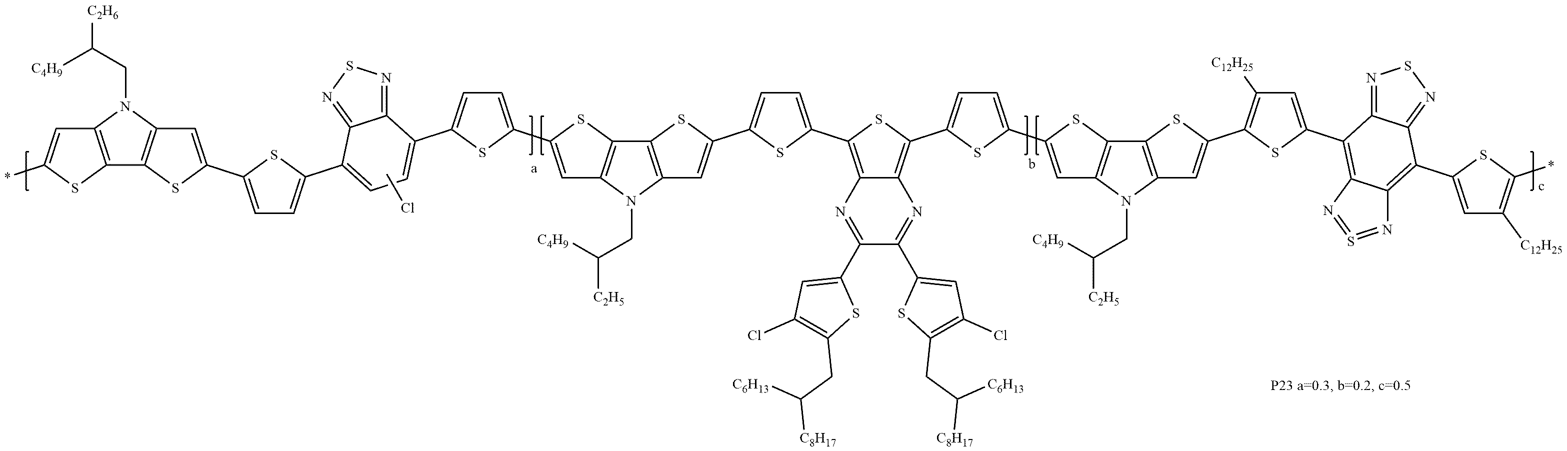

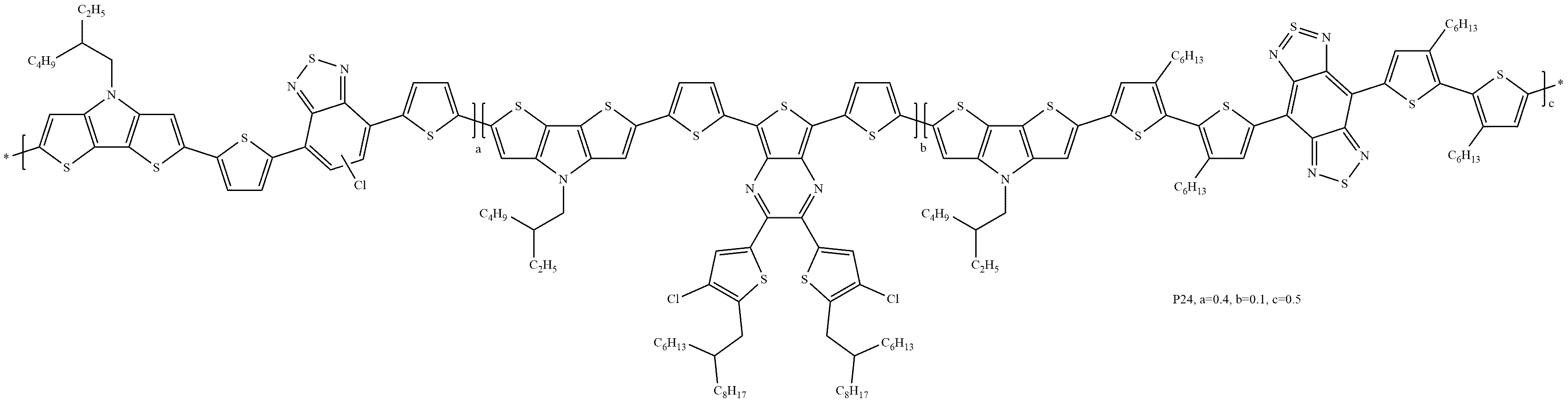

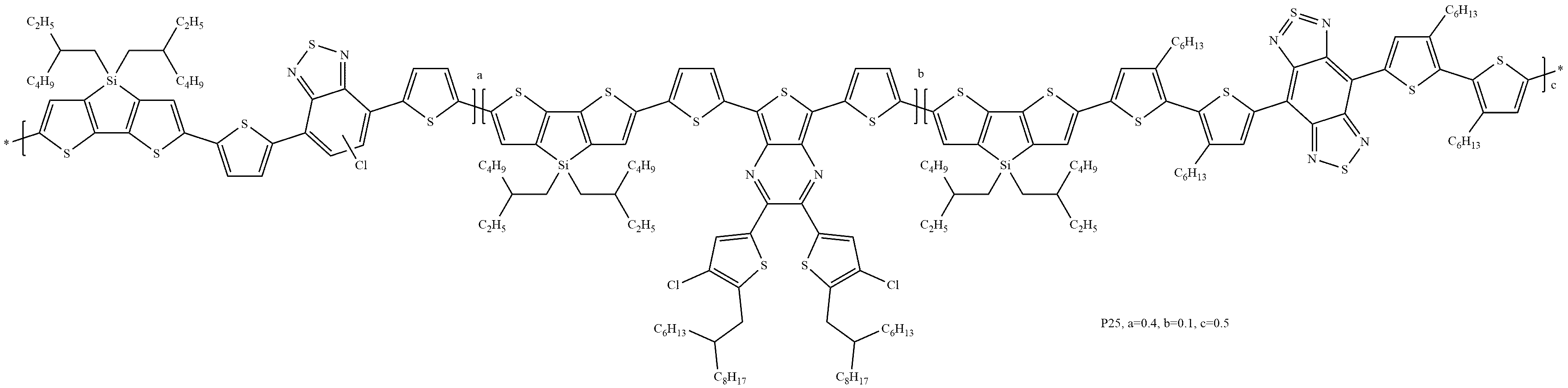

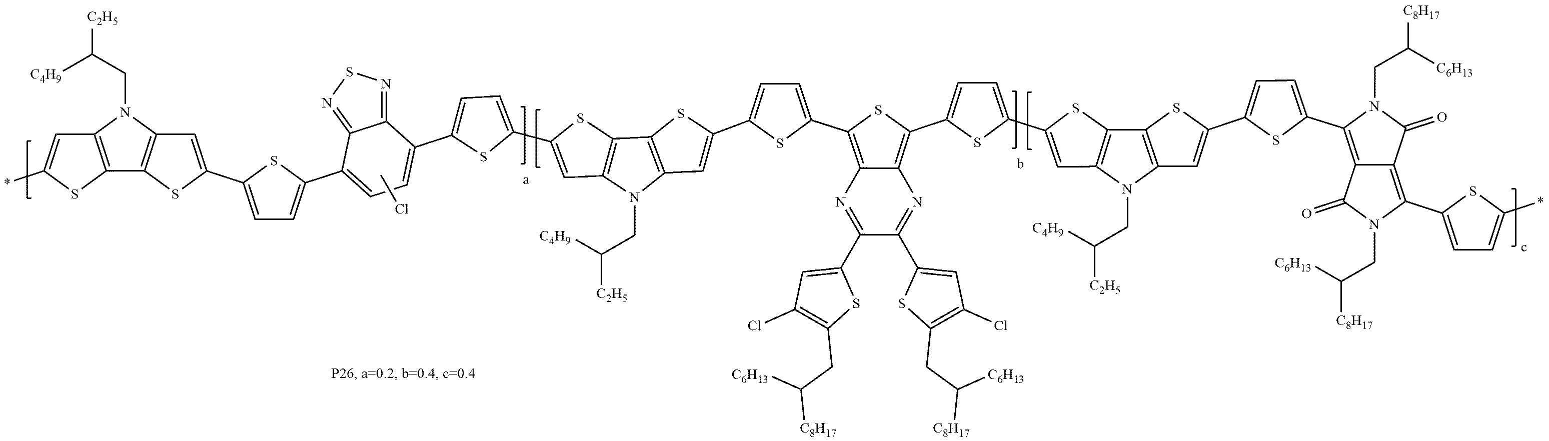

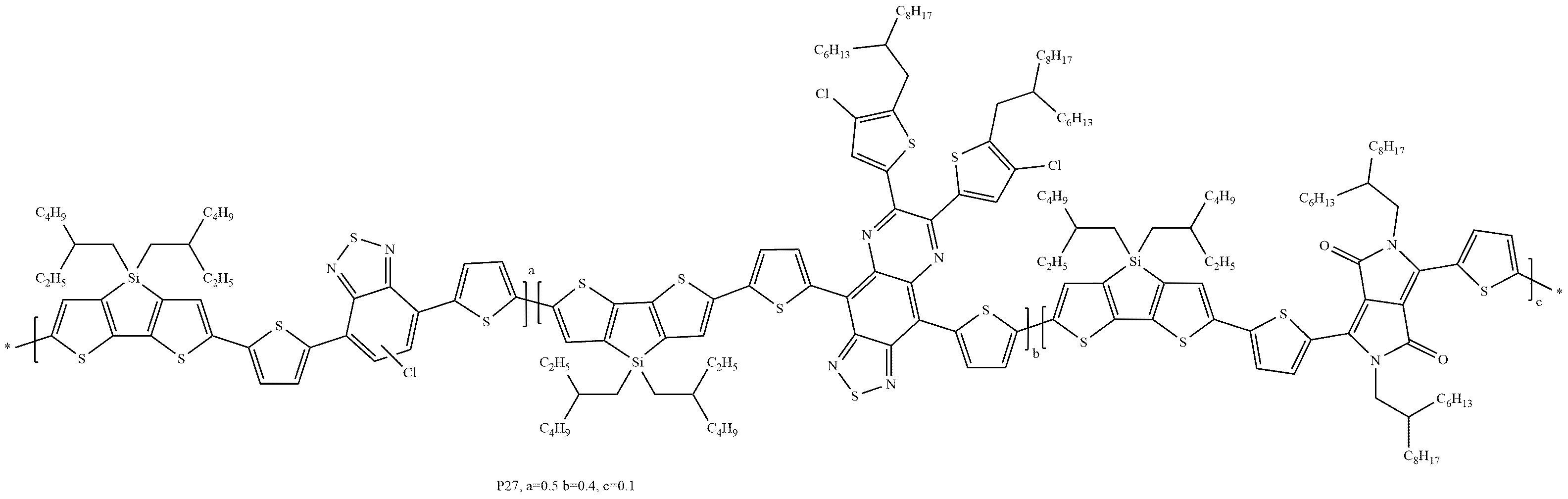

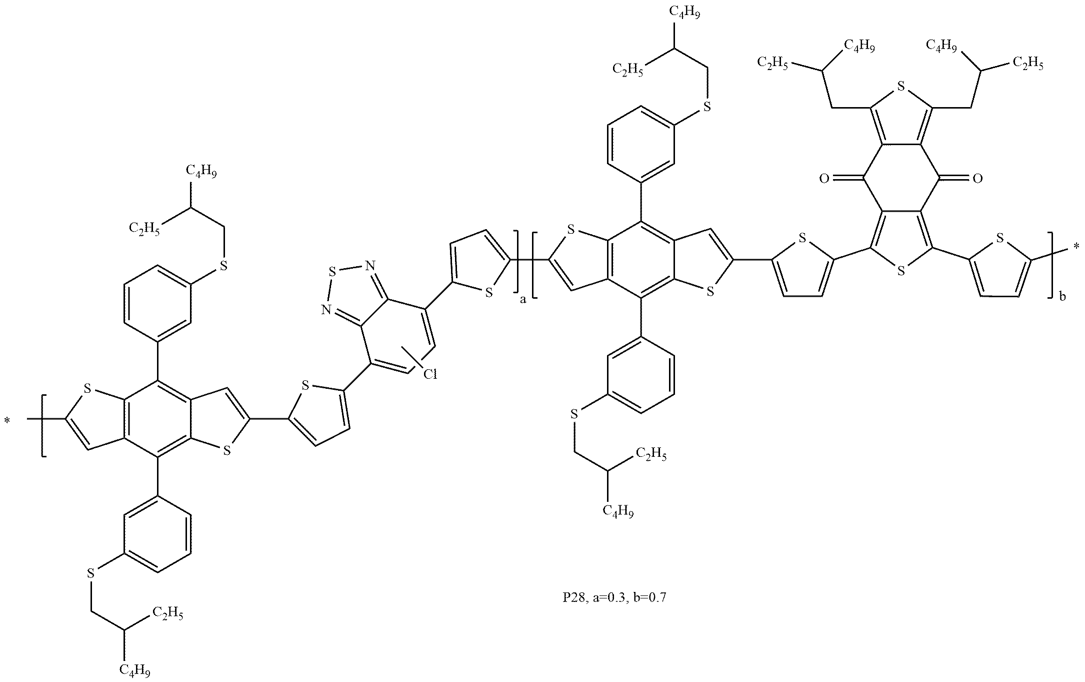

It should be understood that, the above-listed embodiments are only for those skilled in the art to more clearly understand the structural composition of the present invention, and are not limited thereto.

In practice, when A¹ = A² = A³, the absorption wavelength range of the organic optoelectronic device which made by using the conjugated polymer material is only in the visible light region. Therefore, the conjugated polymer material of the present invention can adjust the energy gap by modifying the structure of A² and A³, thereby expanding the absorption wavelength range.

In practice, b and c are not 0 at the same time. Because when b and c are 0 at the same time, only the structure of part a is left, which will cause the absorption wavelength range of the organic optoelectronic device to be only in the visible light region. Therefore, in practical application, b and c are not 0 at the same time in the structure of formula I of the conjugated polymer material of the present invention.

In practice, a is in the range 0.1 to 0.9. In practical applications, a is in the range of 0.3 to 0.9. In further applications, a is in the range of 0.3 to 0.6. Taking the above-mentioned embodiments P1 to P28 as an example, when c = 0, a is in the range of 0.2 to 0.9. In further applications, a is in the range of 0.3-0.9, and further in the range of 0.4-0.7. When a, b, and c are all not 0, a is in the range of 0.1 to 0.9, and in further applications, a is in the range of 0.2 to 0.5. It should be noted that the present invention is conjugated polymer material, and the structure of formula I is the minimum repeating unit of the conjugated polymer material, so the ratio of a, b and c is the equivalent ratio in the minimum repeating unit.

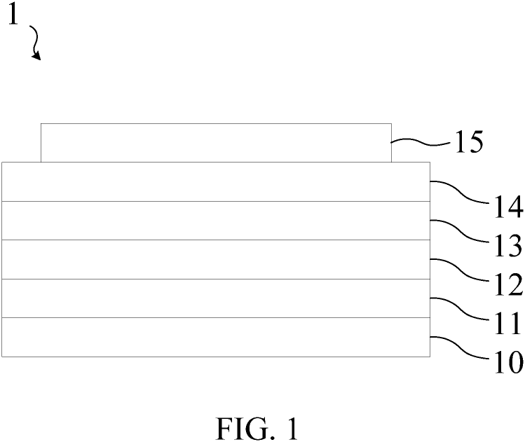

Please refer to FIG. 1. FIG. 1 shows a schematic structural diagram of one embodiment of an organic optoelectronic device of the present invention. As shown in FIG. 1, in another embodiment, the present invention further provides an organic optoelectronic device 1, which comprises a first electrode 11, a second electrode 15 and an active layer 13. The active layer 13, which comprises the aforementioned conjugated polymer material, is disposed between the first electrode 11 and the second electrode 15. In practice, the organic optoelectronic device 1 may have a laminated structure, which sequentially includes a substrate 10, the first electrode 11 (transparent electrode), a first carrier transport layer 12, the active layer 13, a second carrier transport layer 14 and the second electrode 15. In addition, the organic optoelectronic device 1 may include an organic photovoltaic device, an organic photodetector device, an organic light emitting diode, and an organic thin film transistor (OTFT).

In order to illustrate the conjugated polymer material of the present invention more clearly, eight specific embodiments P1~P8 will be used as the P-type material of the active layer, and further prepared into organic optoelectronic devices or organic photodetectors for experiments. Preparation of the active layer:

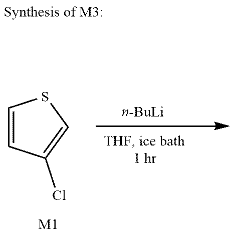

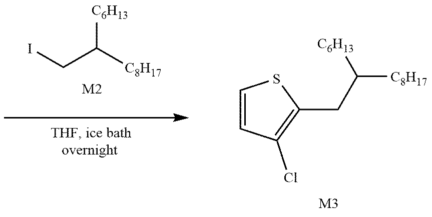

M1 (20.0 g, 169 mmol) was placed into a 250 mL three-neck reaction flask. Under nitrogen, 100 mL of anhydrous THF (tetrahydrofuran) was added to dissolve and cooled down to 15° C. n-BuLi (n-butyllithium) (2.5M in hexane, 45.0 mL, 113 mmol) was added dropwise and slowly, the process was about 30 minutes, the color of solution was pale orange, and the temperature did not exceed 18° C. The reaction mixture was warmed to room temperature and was stirred for 1 hour. At 15° C., M2 (39.8 g, 113 mmol) was added dropwise. The temperature of the reaction mixture was returned to room temperature and the reaction mixture was stirred for 20 hours. 50 mL of water was added to stop the reaction, and after the organic solvent was removed by vacuum rotary evaporator, 100 mL of heptane was added, and the mixture was extracted three times with 100 mL of water. The organic layer was taken to remove water, and the organic solvent was removed by vacuum rotary evaporator to obtain crude product. The starting material and impurities were removed by distillation under reduced pressure (0.25 torr, 170-200° C.). The residue was purified by a silica gel column, and the eluent was heptane. The main segment was collected, the organic solvent was removed, and dried under vacuum to obtain pale yellow oil M3. Yield: 16 g, 41.3%.¹H NMR (500 MHz, CDC1₃) δ 7.09 (d, J = 6.5 Hz, 1H), 6.85 (d, J = 6.5 Hz, 1H), 2.72 (d, J = 7.0 Hz, 2H), 1.68 (m, 1H), 1.27 (m, 24H), 0.88 (m, 6H).

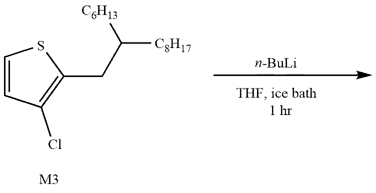

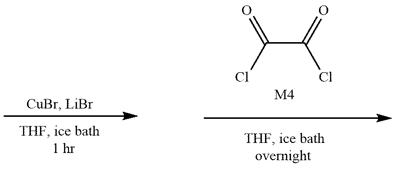

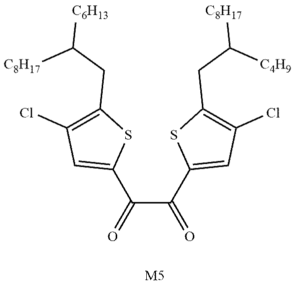

M3 (19.7 g, 57 mmol) was placed into a 500 mL three-neck reaction flask. Under nitrogen, 160 mL of anhydrous THF was added to dissolve and the mixture was cooled down to 10° C. n-BuLi (2.5 M in hexane 22.8 mL, 57 mmol) was added dropwise and slowly, and was stirred for 1 hour. Separately, CuBr (cuprous bromide) (8.2 g, 57 mmol) and LiBr (lithium bromide) (5.0 g, 57 mmol) were placed in another 250 mL three-neck reaction flask, and 160 mL of anhydrous THF was added under nitrogen. The two reaction mixtures were mixed and stirred under 10° C. for 1 hour. At 10° C., M4 (3.3 g, 25.9 mmol) was added to the above mixed solution, and the temperature of the reaction mixture was returned to room temperature and the reaction mixture was stirred for 18 hours. 50 mL of water was added to stop the reaction, and after the organic solvent was removed by vacuum rotary evaporator, 200 mL of heptane was added, and the mixture was extracted three times with 100 mL of water. The organic layer was taken to remove water, and the organic solvent was removed by vacuum rotary evaporator to obtain crude product. The crude product was purified by a silica gel column, and the eluent was Hep : DCM (n-heptane/dichloromethane) = 4 : 1. The main segment was collected, the organic solvent was removed, and dried under vacuum to obtain yellow oil M5. Yield: 13.3 g, 71.5 %.¹H NMR (500 MHz, CDC1₃) δ 7.88 (s, 2H), 2.80 (d, J = 7.0 Hz, 4H), 1.76 (m, 2H), 1.29 (m, 48H), 0.88 (m, 12H).

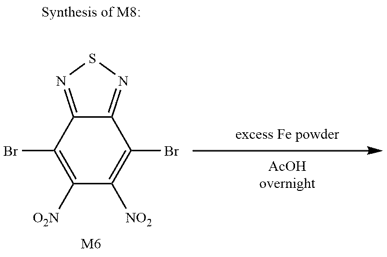

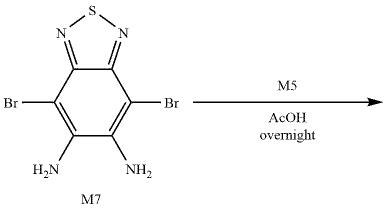

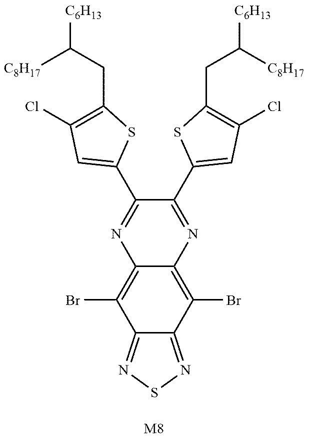

M6 (2.0 g, 5.2 mmol) was placed into a 250 mL two-neck reaction flask. 60 mL of glacial acetic acid was added. The reaction mixture was stirred in room temperature. Under nitrogen, 5.8 g of iron powder was added. The reaction mixture was heated to 120° C., and stirred overnight. The temperature of the reaction mixture was cooled to room temperature, and the reaction mixture was quenched by the addition of 150 g ice water. The reaction mixture was filtered, and the solid of the reaction mixture was rinsed with ice water to collect the khaki solid. The khaki solid was dissolved in 150 mL of THF and filtered to remove residual grey solid. The organic solvent was removed by vacuum rotary evaporator and after vacuum drying, a green-brown crude product M7 was obtained, 1.35 g. M7 (1.3 g, 4.1 mmol) and M5 (2.7 g, 3.8 mmol) was placed into a 250 mL one-neck reaction flask, and 60 mL of glacial acetic acid was added. Under nitrogen, the reaction mixture was heated to 120° C., and stirred overnight. The temperature of the reaction mixture was cooled to room temperature, and the reaction mixture was quenched by the addition of 100 mL of water. The mixture was extracted three times with 100 mL of DCM. The organic layer was extracted three times with 100 mL of water. The organic layer was dried with MgSO₄, and the organic solvent was removed by vacuum rotary evaporator to obtain crude product. The crude product was purified by a silica gel column, and the eluent was Heptane : DCM = 4 : 1. The main segment was collected, the organic solvent was removed, and dried under vacuum to obtain bright red solid M8. Yield: 2.4 g, 61.6 %.¹H NMR (500 MHz, CDC1₃) δ 7.45 (s, 2H), 2.83 (d, J = 7.0 Hz, 4H), 1.83 (m, 2H), 1.30 (m, 48H), 0.89 (m, 12H).

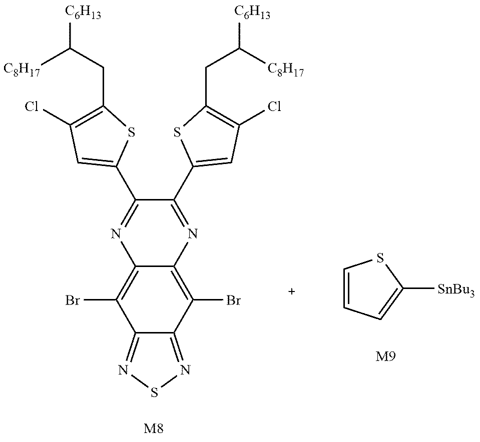

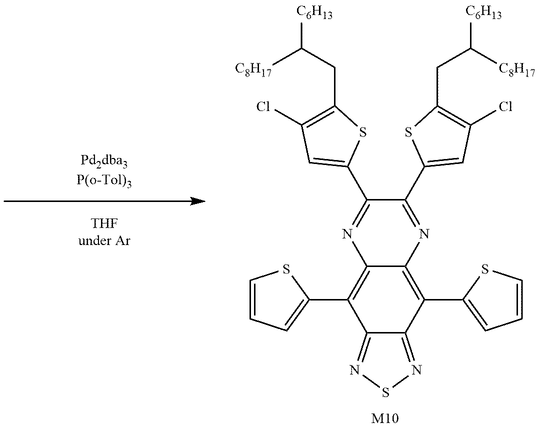

M8 (2 g, 1.942 mmol) and M9 (1.60 g, 4.287 mmol) were placed in a 100 mL double-neck reaction flask, and 40 mL of THF was added. The solution was purged with argon for 15 minutes. Pd₂(dba)₃ (tris(dibenzylideneacetone) dipalladium) (0.071 g, 0.078 mmol) and P(o-tolyl)₃ (tris(o-tolyl)phosphine) (0.095 g, 0.311 mmol) were added, and the reaction mixture was heated to 66° C. and stirred for 2 hours. After cooling, the reaction mixture was filtered through celite, rinsed with heptane, and removed the organic solution by a vacuum rotary evaporator. The crude product was purified by column chromatography with silica gel, and the eluent was Heptane : DCM = 9 : 1. The main segment was collected and concentrated to obtain a brown viscous liquid M10. Yield: 1.81 g, 90.1%. ¹H NMR (600 MHz, CDC1₃) δ 8.88 (d, J = 4.8 Hz, 2H), 7.71 (d, J = 4.8 Hz, 2H), 7.43 (s, 2H), 7.34 (t, J = 6.0 Hz, 2H), 2.85 (d, J = 8.4 Hz, 4H), 1.83 (m, 2H), 1.30 (m, 48H), 0.88 (m, 12H).

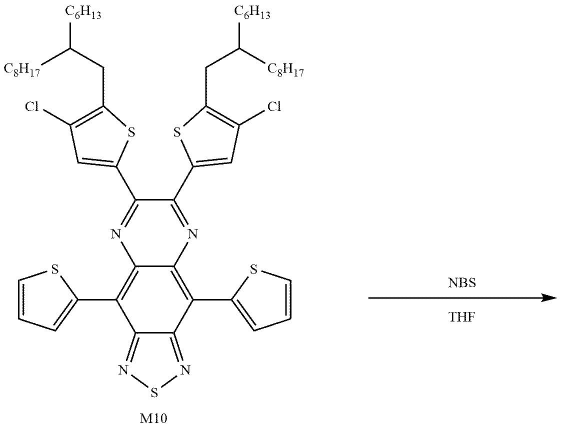

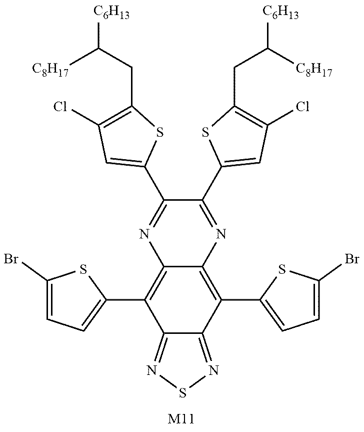

M10 (1.81 g, 1.75 mmol) was replaced into a 100 mL three-neck reaction flask. Under nitrogen, 107 mL of THF was added. Under an ice bath (< 10° C.), NBS (N-bromosuccinimide) (0.716 g, 4.023 mmol) was added. The reaction mixture was stirred at room temperature for 18 hours. The organic solvent was removed by a vacuum rotary evaporator. The crude product was purified by column chromatography with silica gel, and the eluent was Heptane : DCM = 19 : 1. The main segment was collected and concentrated to a dark brown viscous liquid M11. Yield: 1.88 g, 89.8%. ¹H NMR (600 MHz, CDC1₃) δ 8.73 (d, J = 5.4 Hz, 2H), 7.38 (s, 2H), 7.21 (t, J = 4.8 Hz, 2H), 2.88 (d, J = 8.4 Hz, 4H), 1.87 (m, 2H), 1.29 (m, 48H), 0.85 (m, 12H).

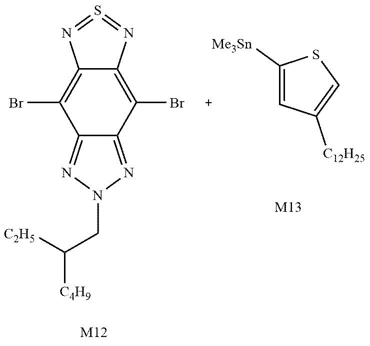

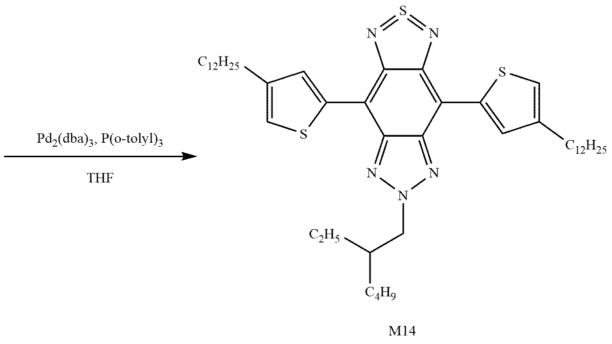

M12 (1.0 g, 2.226 mmol) and M13 (2.4 g, 5.779 mmol) were placed into a 100 mL three-neck reaction flask. 45 mL of THF was added and the reaction mixture was purged with argon for 15 minutes. Pd₂(dba)₃ (0.082 g, 0.090 mmol) and P(o-tolyl)₃ (0.108 g, 0.355 mmol) were added, and the reaction mixture was heated to 66° C. and stirred for 2 hours. After cooling, the reaction mixture was filtered through celite, rinsed with heptane, and the organic solution was removed by a vacuum rotary evaporator. The crude product was purified by column chromatography with silica gel, and the eluent was DCM/Heptane = ¼. The main segment was collected and concentrated to obtain a black-blue solid M14. Yield: 1.64 g, 93.2%. ¹H NMR (500 MHz, CDC1₃) δ 8.69 (s, 2H), 7.23 (s, 2H), 4.91 (d, J = 7.2 Hz, 2H), 2.76 (m, 4H), 2.38 (s, 1H), 1.74 (m, 4H), 1.38 (m, 2H), 1.07 (m, 42H), 0.89 (m, 12H).

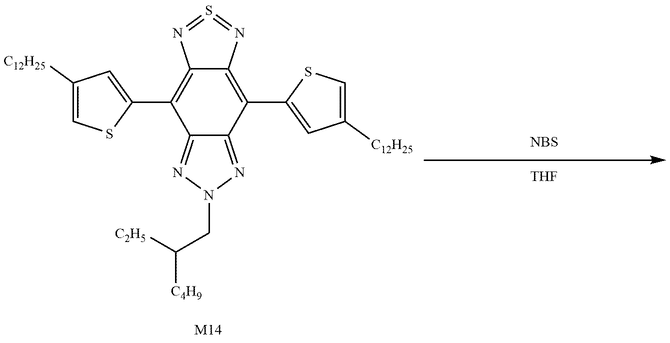

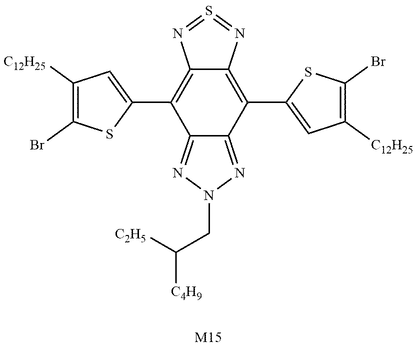

M14 (1.0 g, 1.265 mmol) was replaced into a 100 mL three-neck reaction flask. Under nitrogen, 45 mL of THF was added. The mixture was cooled under 10° C., and NBS (0.450 g, 2.528 mmol) was added. The reaction mixture was stirred at room temperature for 18 hours. The organic solvent was removed by a vacuum rotary evaporator. The crude product was purified by column chromatography with silica gel, and the eluent was DCM/Heptane = ¼. The main segment was collected and concentrated to a black-blue solid M15. Yield: 1.15 g, 95.6%. ¹H NMR (600 MHz, CDC1₃) δ 8.54 (s, 2H), 4.95 (m, 2H), 2.70 (m, 4H), 2.38 (s, 1H), 1.74 (m, 4H), 1.38 (m, 2H), 1.07 (m, 42H), 0.88 (m, 12H).

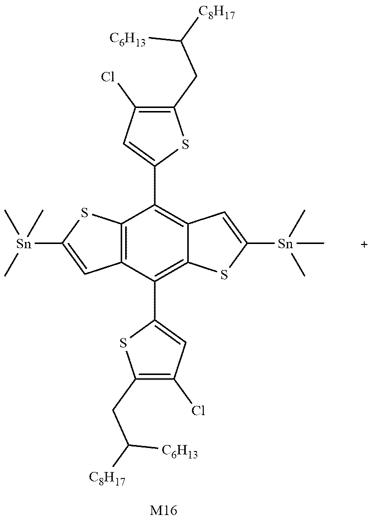

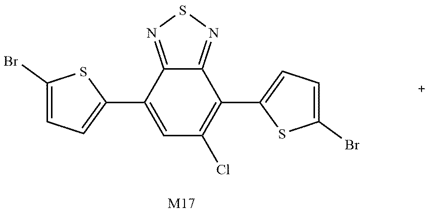 [SMILES: Clc1cc(-c2ccc(Br)s2)c2nsnc2c1-c1ccc(Br)s1 ; "M17"]

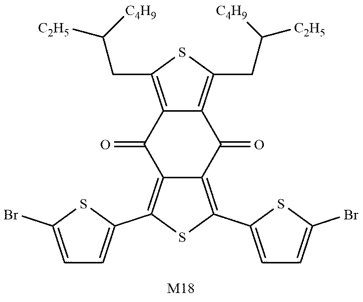

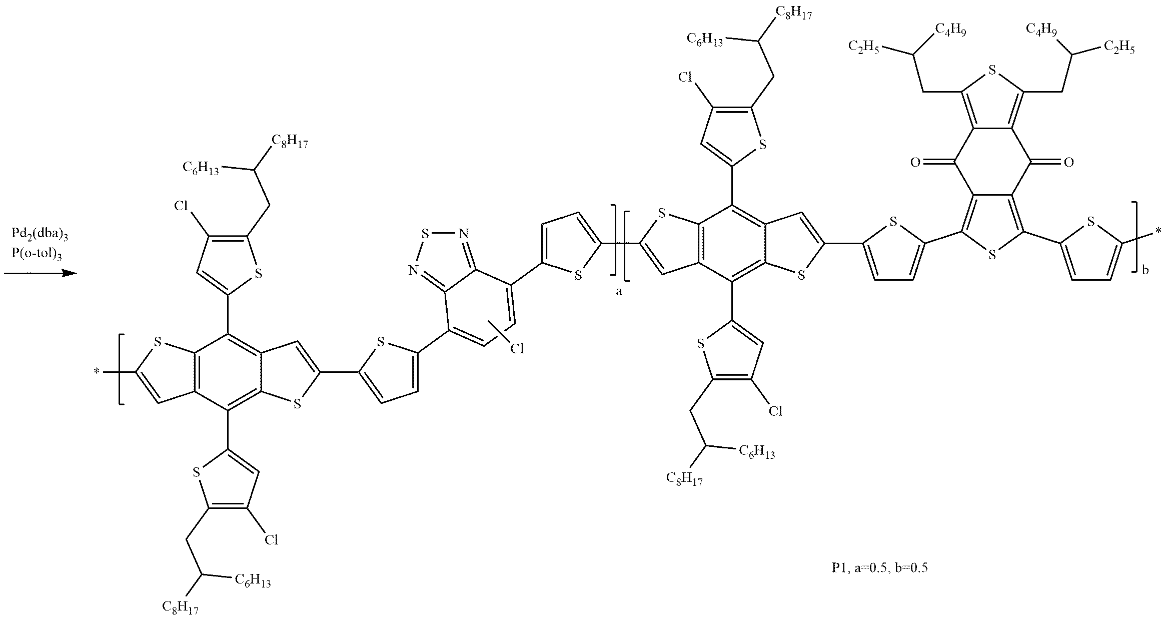

The starting materials M16 (0.32 g, 0.27 mmol), M17 (0.066 g, 0.13 mmol) and M18 (0.10 g, 0.13 mmol) were placed into a two-neck flask, 30 mL of chlorobenzene was added and purged with argon for 30 mins. Pd₂(dba)₃ (0.0098 g, 0.011 mmol) and P(o-tolyl)₃ (0.013 g, 0.043 mmol) were added under argon. The mixture was heated overnight in a 130° C. oil bath. After cooling to room temperature, the mixture was poured into methanol to precipitate. The polymer was purified by Soxhlet extraction using methanol followed by dichloromethane. The purified solid was dissolved in chlorobenzene and then precipitated in methanol. The solid was dried to obtain product P1. Yield: 0.28 g, 79.3%.

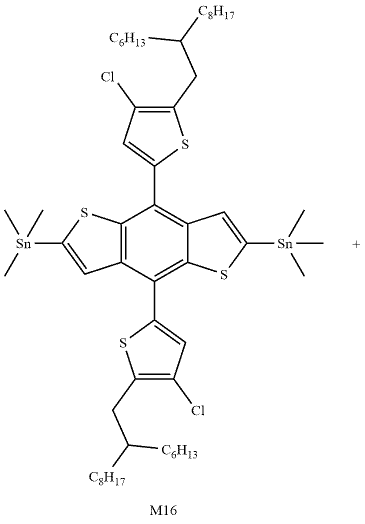

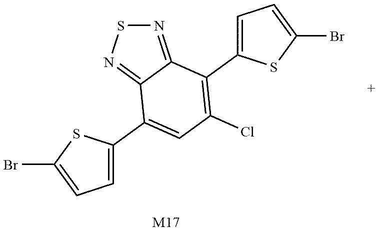

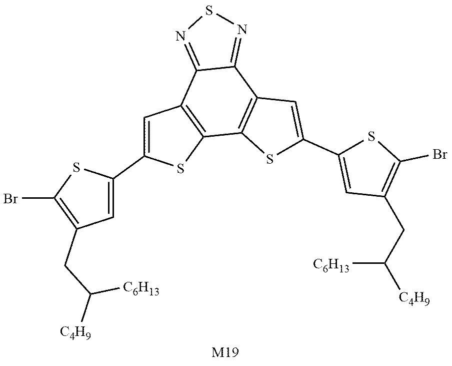

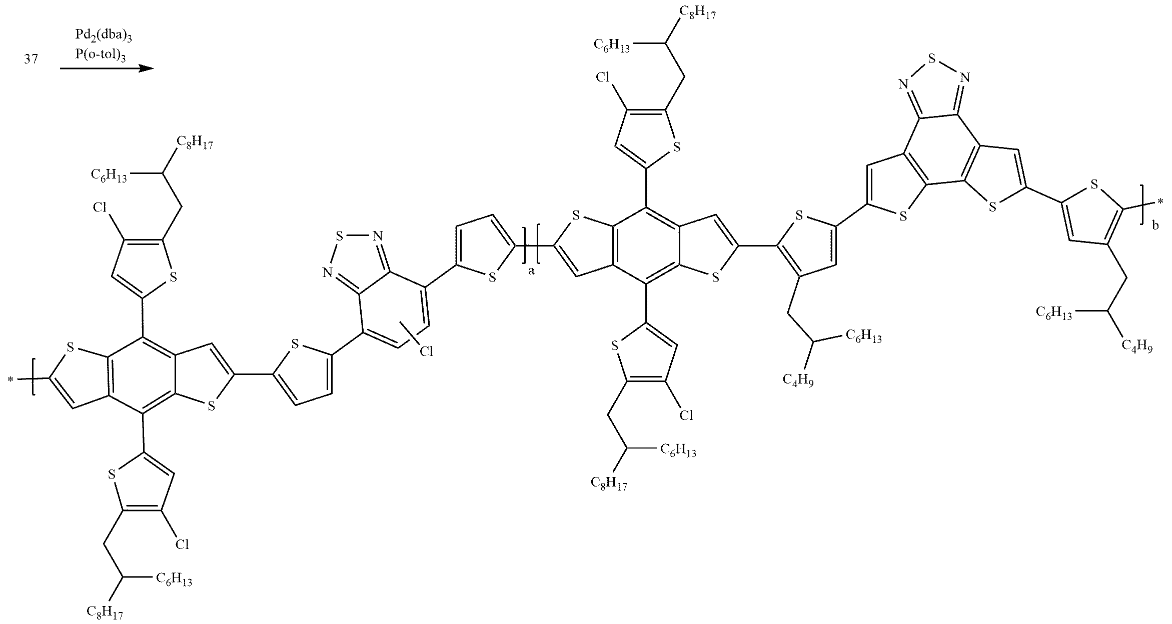

The starting materials M16 (0.31 g, 0.26 mmol), M17 (0.065 g, 0.13 mmol) and M19 (0.12 g, 0.13 mmol) were placed into a two-neck flask, 30 mL of chlorobenzene was added and purged with argon for 30 mins. Pd₂(dba)₃ (0.0096 g, 0.011 mmol) and P(o-tolyl)₃ (0.013 g, 0.042 mmol) were added under argon. The mixture was heated overnight in a 130° C. oil bath. After cooling to room temperature, the mixture was poured into methanol to precipitate. The polymer was purified by Soxhlet extraction using methanol followed by dichloromethane. The purified solid was dissolved in chlorobenzene and then precipitated in methanol. The solid was dried to obtain product P2. Yield: 0.18 g, 51.8%.

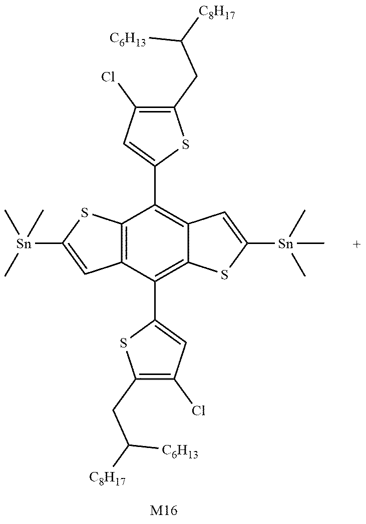

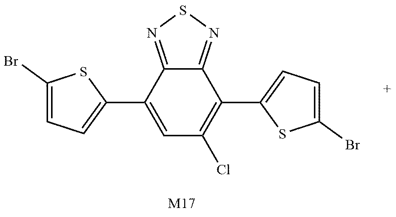

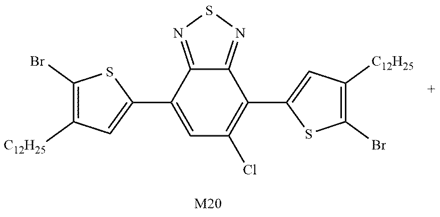

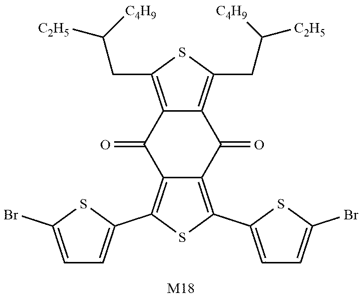

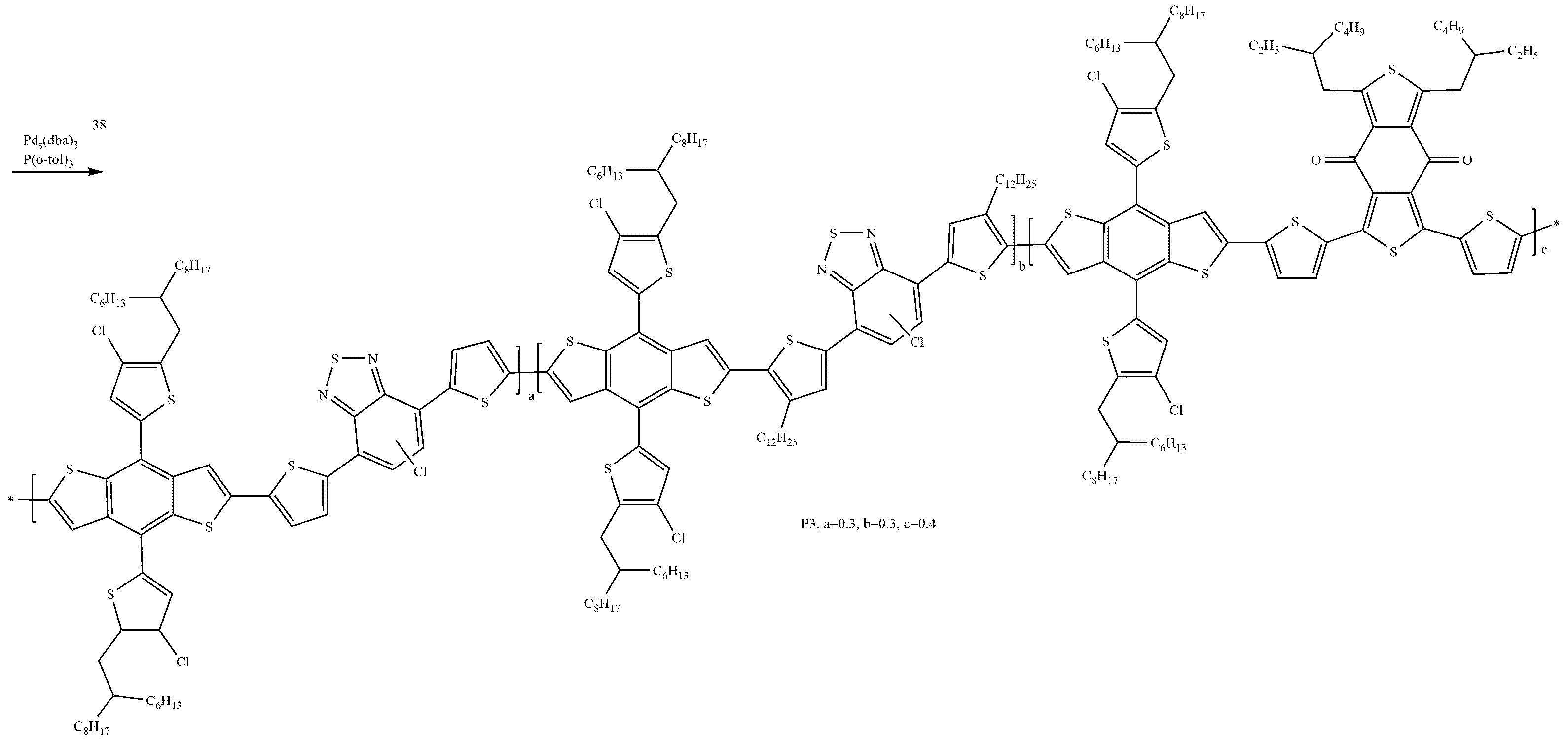

The starting materials M16 (0.50 g, 0.42 mmol), M17 (0.062 g, 0.126 mmol), M20 (0.10 g, 0.126 mmol) and M18 (0.13 g, 0.17 mmol) were placed into a two-neck flask, 50 mL of chlorobenzene was added and purged with argon for 30 mins. Pd₂(dba)₃ (0.015 g, 0.017 mmol) and P(o-tolyl)₃ (0.020 g, 0.067 mmol) were added under argon. The mixture was heated in a 130° C. oil bath for 6 hours. After cooling to room temperature, the mixture was poured into methanol to precipitate. The polymer was purified by Soxhlet extraction using methanol followed by dichloromethane. The purified solid was dissolved in chlorobenzene and then precipitated in methanol. The solid was dried to obtain product P3. Yield: 0.48 g, 80.8%.

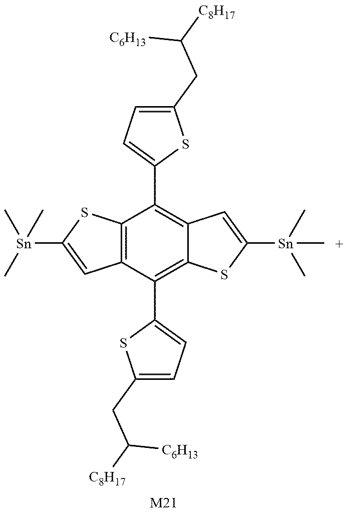

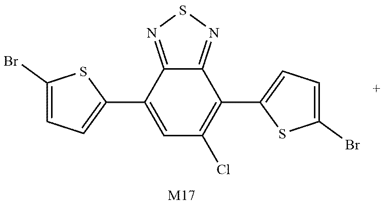

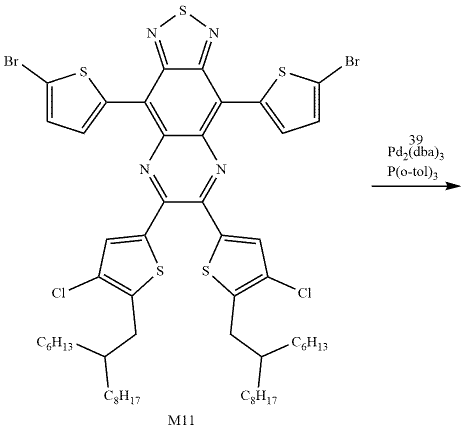

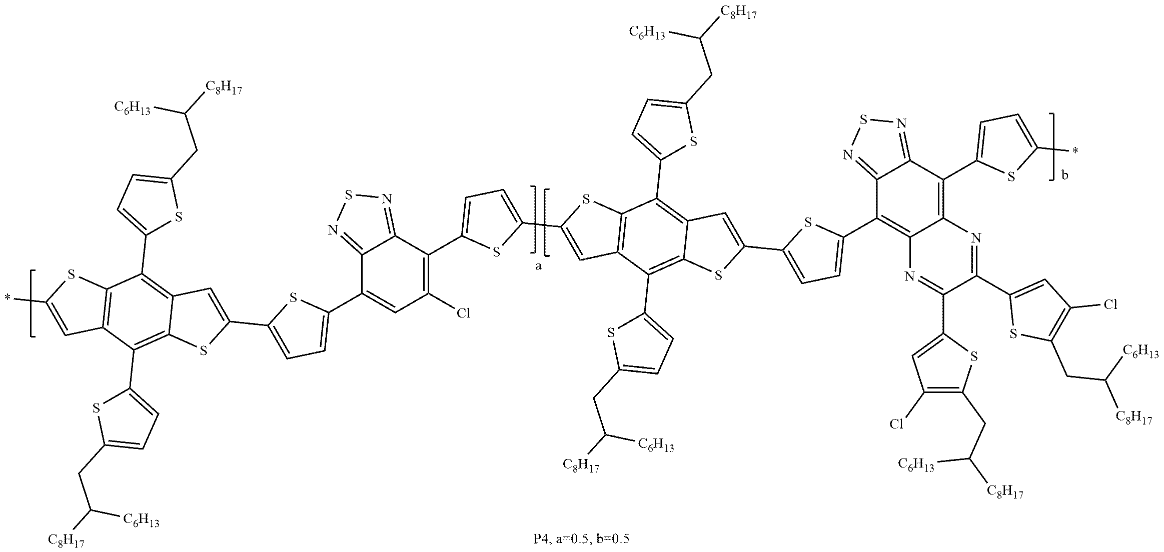

The starting materials M21 (0.20 g, 0.17 mmol), M17 (0.043 g, 0.088 mmol) and M11 (0.10 g, 0.088 mmol) were placed into a two-neck flask, 20 mL of xylene was added and purged with argon for 30 mins. Pd₂(dba)₃ (0.0064 g, 0.007 mmol) and P(o-tolyl)₃ (0.0085 g, 0.028 mmol) were added under argon. The mixture was heated overnight in a 130° C. oil bath. After cooling to room temperature, the mixture was poured into methanol to precipitate. The polymer was purified by Soxhlet extraction using methanol followed by dichloromethane. The purified solid was dissolved in chlorobenzene and then precipitated in methanol. The solid was dried to obtain product P4. Yield: 0.147 g, 56.6%.

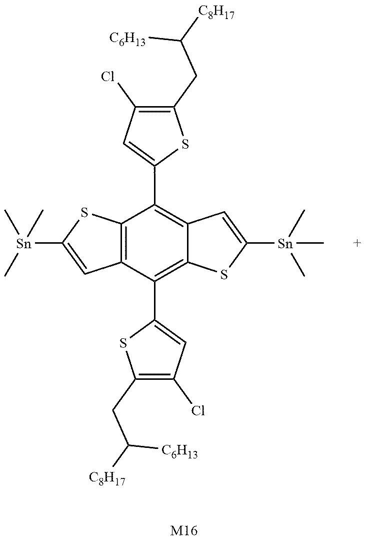

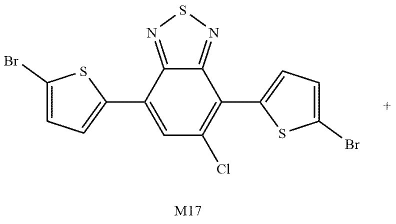

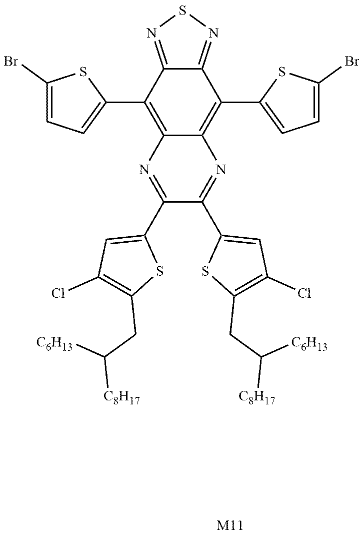

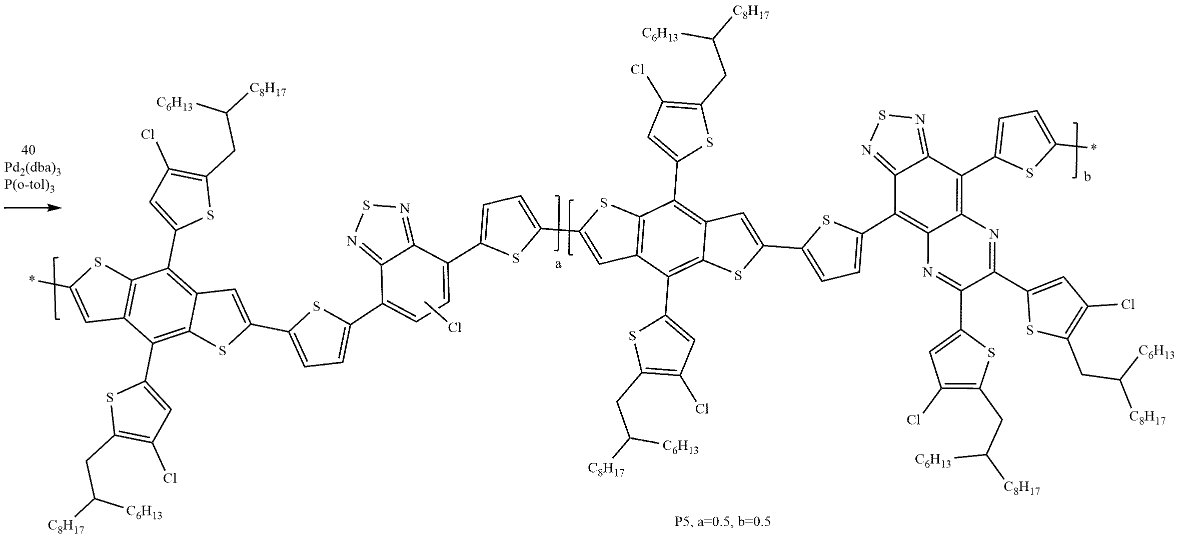

The starting materials M16 (0.20 g, 0.17 mmol), M17 (0.041 g, 0.084 mmol) and M11 (0.10 g, 0.084 mmol) were placed into a two-neck flask, 20 mL of chlorobenzene was added and purged with argon for 30 mins. Pd₂(dba)₃ (0.0062 g, 0.007 mmol) and P(o-tolyl)₃ (0.0082 g, 0.027 mmol) were added under argon. The mixture was heated overnight in a 130° C. oil bath. After cooling to room temperature, the mixture was poured into methanol to precipitate. The polymer was purified by Soxhlet extraction using methanol followed by ethyl acetate. The purified solid was dissolved in chlorobenzene and then precipitated in methanol. The solid was dried to obtain product P5. Yield: 0.22 g, 84%.

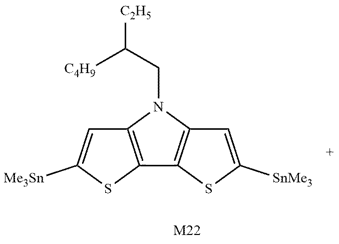

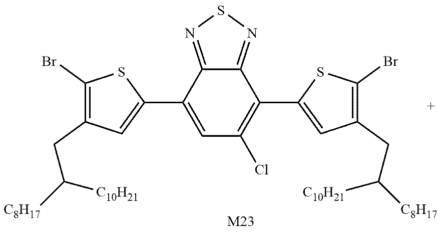

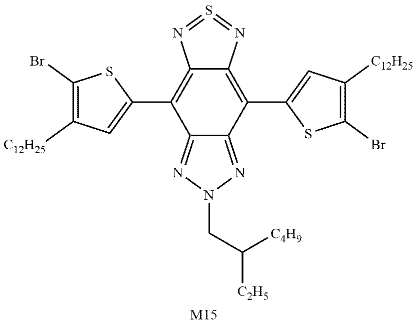

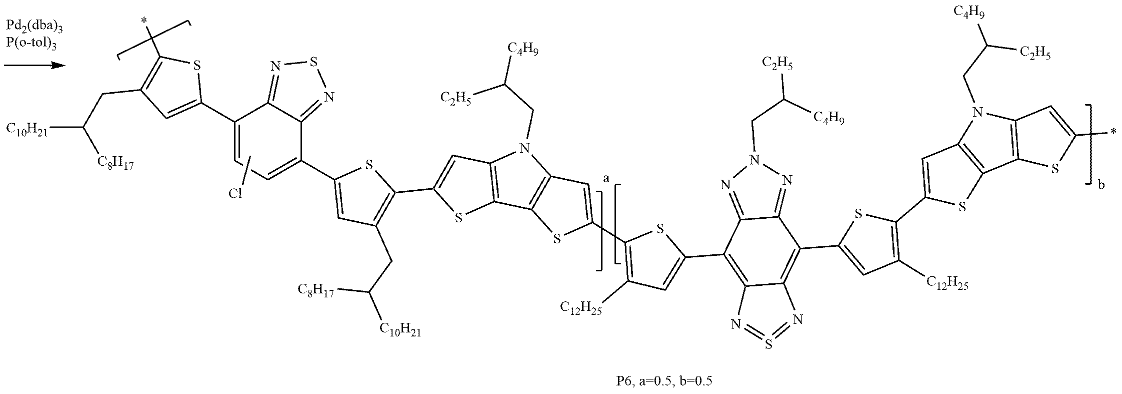

The starting materials M22 (0.150 g, 0.24 mmol), M23 (0.128 g, 0.12 mmol) and M15 (0.115 g, 0.12 mmol) were placed into a two-neck flask, 10.5 mL of chlorobenzene was added and purged with argon for 30 mins. Pd₂(dba)₃ (0.0022 g, 0.0024 mmol) and P(o-tolyl)₃ (0.0030 g, 0.0097 mmol) were added under argon. The mixture was heated in a 130° C. oil bath for 13.5 minutes. After cooling to room temperature, the mixture was poured into methanol to precipitate. The polymer was purified by Soxhlet extraction using methanol followed by dichloromethane. The purified solid was dissolved in chlorobenzene and then precipitated in methanol. The solid was dried to obtain product P6. Yield: 0.176 g, 64.1%.

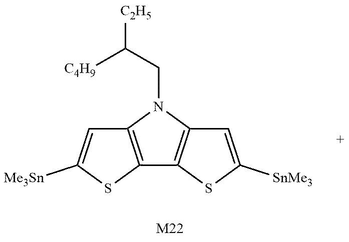

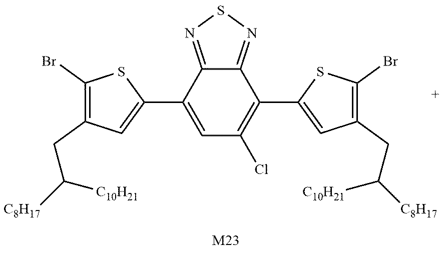

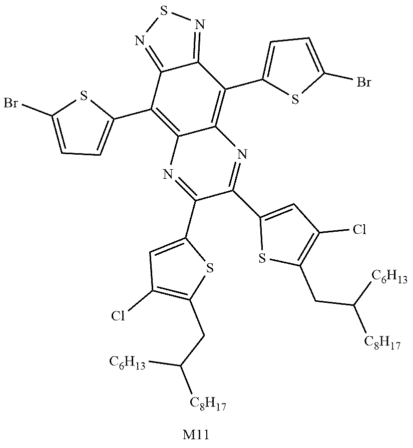

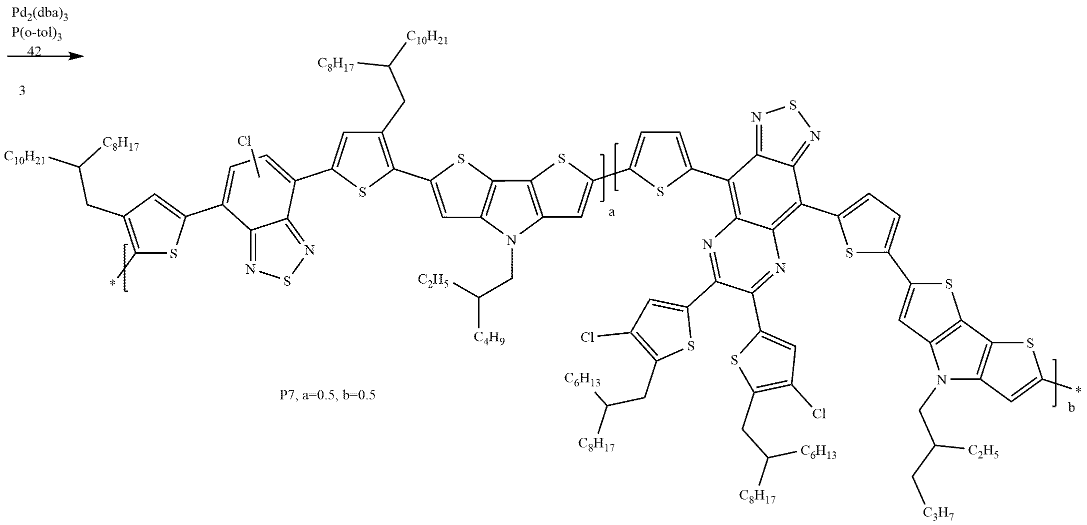

The starting materials M22 (0.150 g, 0.24 mmol), M23 (0.128 g, 0.12 mmol) and M11 (0.149 g, 0.12 mmol) were placed into a two-neck flask, 10.5 mL of chlorobenzene was added and purged with argon for 30 mins. Pd₂(dba)₃ (0.0022 g, 0.0024 mmol) and P(o-tolyl)₃ (0.0030 g, 0.0097 mmol) were added under argon. The mixture was heated in a 130° C. oil bath for 1 hour. After cooling to room temperature, the mixture was poured into methanol to precipitate. The polymer was purified by Soxhlet extraction using methanol followed by dichloromethane. The purified solid was dissolved in chlorobenzene and then precipitated in methanol. The solid was dried to obtain product P7. Yield: 0.158 g, 51.9%.

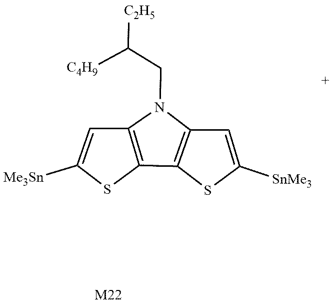

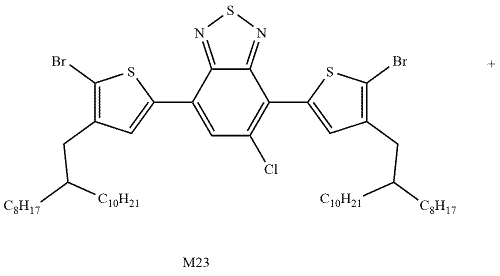

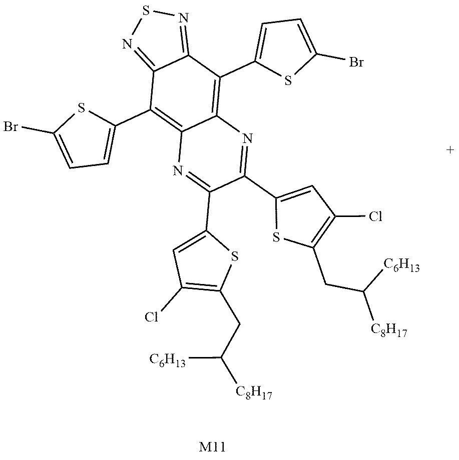

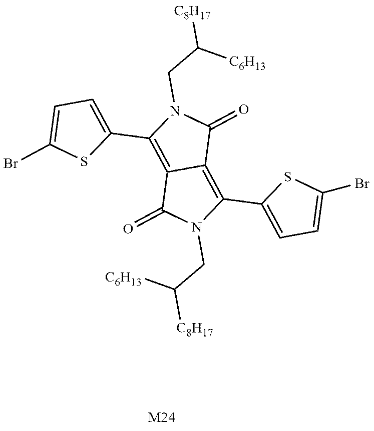

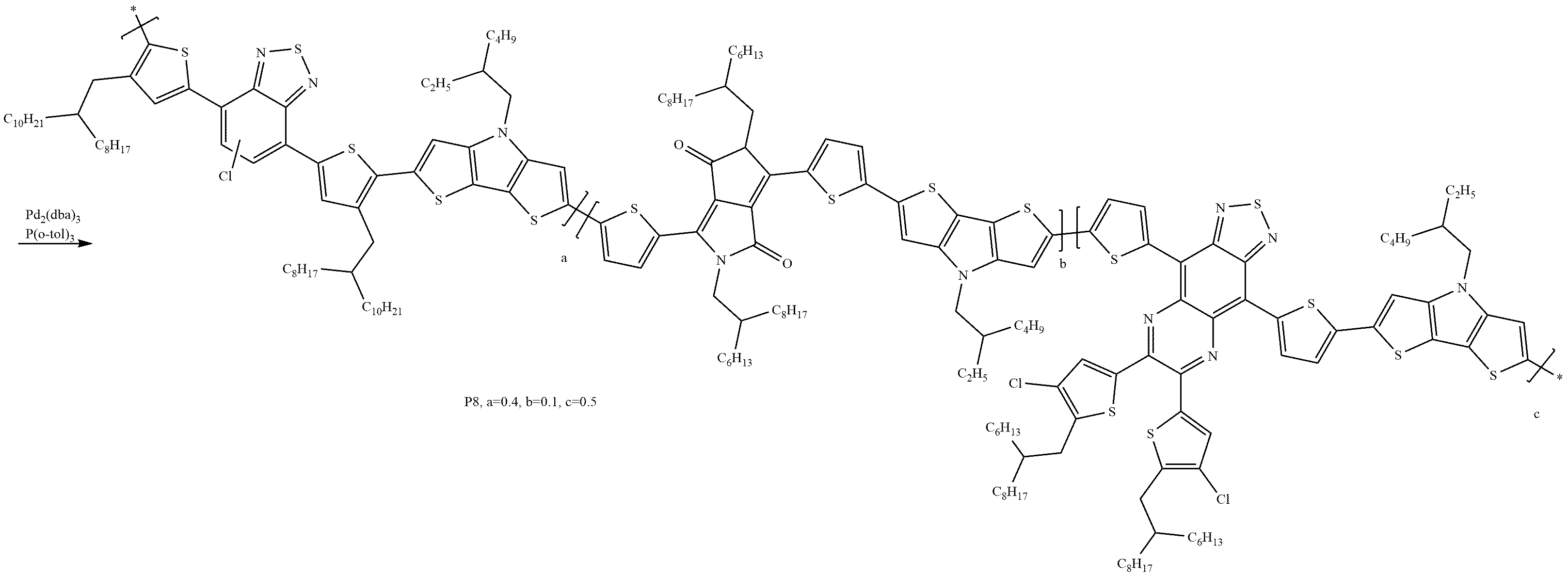

The starting materials M22 (0.150 g, 0.24 mmol), M23 (0.102 g, 0.10 mmol), M11 (0.149 g, 0.12 mmol) and M24 (0.022 g, 0.02 mmol) were placed into a two-neck flask, 10.5 mL of chlorobenzene was added and purged with argon for 30 mins. Pd₂(dba)₃ (0.0022 g, 0.0024 mmol) and P(o-tolyl)₃ (0.0030 g, 0.0097 mmol) were added under argon. The mixture was heated in a 130° C. oil bath for 16 minutes. After cooling to room temperature, the mixture was poured into methanol to precipitate. The polymer was purified by Soxhlet extraction using methanol followed by dichloromethane. The purified solid was dissolved in chlorobenzene and then precipitated in methanol. The solid was dried to obtain product P8. Yield: 0.256 g, 85.0%.

Characteristic test of conjugated polymer materials P1 to P8:

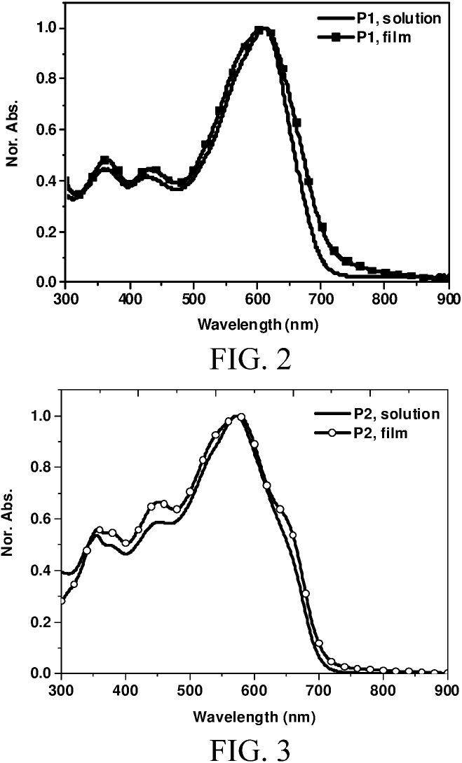

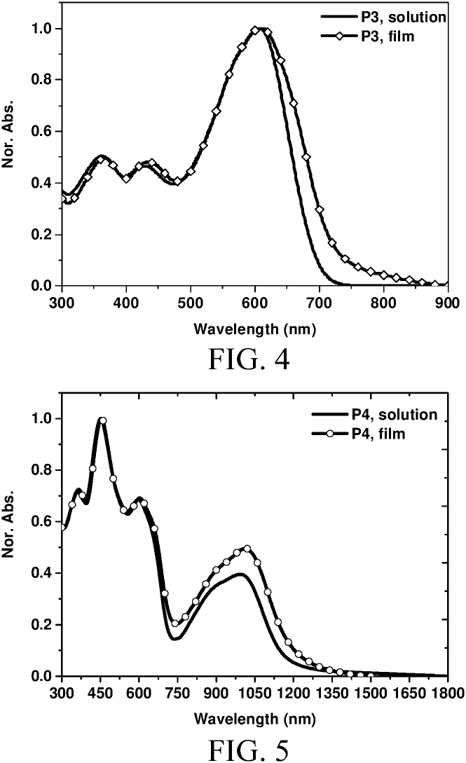

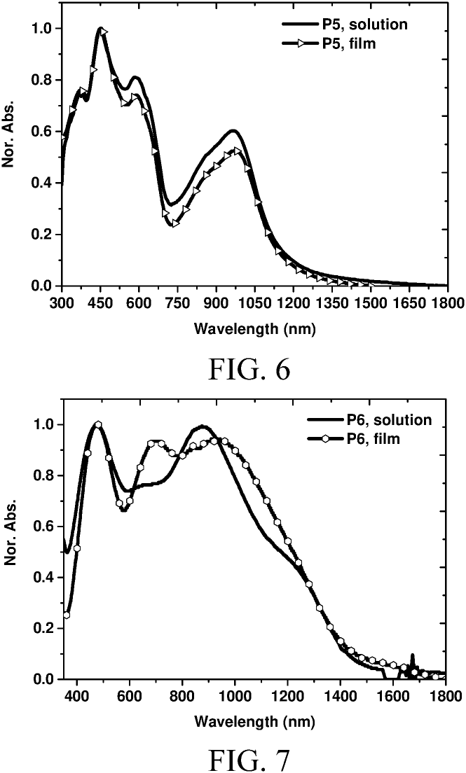

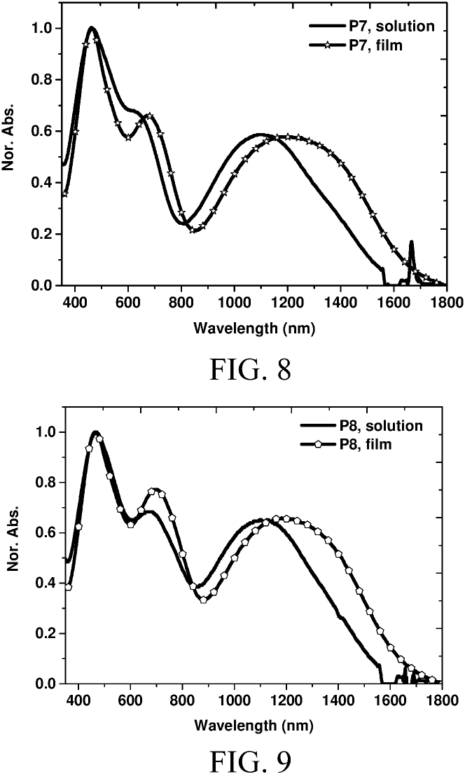

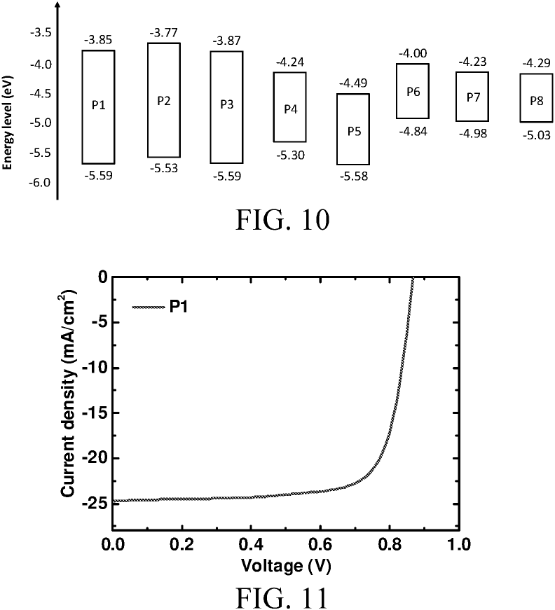

Please refer to FIG. 2 to FIG. 10 and Table 1. FIG. 2 shows an absorption spectra of an embodiments P1 of the conjugated polymer material of the present invention in solution state and thin film state. FIG. 3 shows an absorption spectra of an embodiments P2 of the conjugated polymer material of the present invention in solution state and thin film state. FIG. 4 shows an absorption spectra of an embodiments P3 of the conjugated polymer material of the present invention in solution state and thin film state. FIG. 5 shows an absorption spectra of an embodiments P4 of the conjugated polymer material of the present invention in solution state and thin film state. FIG. 6 shows an absorption spectra of an embodiments P5 of the conjugated polymer material of the present invention in solution state and thin film state. FIG. 7 shows an absorption spectra of an embodiments P6 of the conjugated polymer material of the present invention in solution state and thin film state. FIG. 8 shows an absorption spectra of an embodiments P7 of the conjugated polymer material of the present invention in solution state and thin film state. FIG. 9 shows an absorption spectra of an embodiments P8 of the conjugated polymer material of the present invention in solution state and thin film state. FIG. 10 shows a schematic energy level diagram of eight embodiments P1 to P8 of the conjugated polymer materials of the present invention. Table 1 shows the data results of FIG. 2 to FIG. 10.

Table 1

The data results of FIG. 2 to FIG. 10

| sample | λₛₒₗₙ ^{max} (nm) | ε (10⁴ cm⁻¹ M⁻ ¹) | λ_{film}^{max} (nm) | λ_{film}onset (nm) | E_{g}^{opt} (eV) | HOMO (eV) | LUMO (eV) |
|---|---|---|---|---|---|---|---|
| P1 | 610 | 6.1 | 610 | 713 | 1.74 | -5.59 | -3.85 |
| P2 | 571 | 5.5 | 574 | 705 | 1.76 | -5.53 | -3.77 |
| P3 | 607 | 5.0 | 609 | 721 | 1.72 | -5.59 | -3.87 |
| P4 | 450, 601, 994 | 1.7 | 450, 601, 1016 | 1171 | 1.06 | -5.3 | -4.24 |
| P5 | 450, 583, 965 | 1.4 | 450, 590, 969 | 1138 | 1.09 | -5.58 | -4.49 |
| P6 | 476, 875 | 2.1 | 476, 700, 927 | 1477 | 0.84 | -4.84 | -4.00 |
| P7 | 465, 1098 | 1.9 | 461, 673, 1190 | 1655 | 0.75 | -4.98 | -4.23 |
| P8 | 468, 672, 1100 | 1.1 | 465, 697, 1193 | 1677 | 0.74 | -5.03 | -4.29 |

The oxidation properties of P1 to P8 are measured by cyclic voltammetry. The highest occupied molecular orbital (HOMO) is calculated from HOMO =-|4.71+E^{ox}-E^{ferroncene}|eV. The optical energy gap (E_{g} = 1241/λ_{film}^{onset} eV) of the material is known from the absorption onset position (λ_{film}^{onset}) of the UV-Vis-NIR absorption spectrum in film state. The lowest unoccupied molecular orbital (LUMO) is calculated from LUMO = HOMO + E_{g} eV. It can be clearly seen from the absorption spectra of FIG. 2 to FIG. 9 that there are three types of patterns and absorption ranges, which are P1 to P3, P4 and P5, and P6 to P8, respectively. From FIG. 10, it can be found that it can be divided into P1 to P3 with wide energy gap, P4 and P5 with narrow energy gap, and P6 to P8 with ultra-narrow energy gap according to the different energy gap. Therefore, it can be clearly seen from FIG. 10 that the introduction of different A² and A³ structures into the structure of Formula I can effectively change the energy gap and light absorption range of the material. It is further verified that the conjugated polymer material of the present invention can arbitrarily control the light absorption range of the material. P1 to P3 as a wide energy gap material and can be applied to organic photovoltaic (OPV) which the absorption range mainly falls in the visible region. P4 to P8 combine the A² and A³ structures with different electron-withdrawing abilities, which lead to changes in the charge transfer effect of the conjugated polymer materials, so that the absorption range of the conjugated polymer materials can be extended to more than 1000 nm. In this regard, P4 to P8 as a narrow energy gap and an ultra-narrow energy gap materials and can be applied to the organic photodetector (OPD) which the absorption range includes the visible light region and the near-infrared region. As can be seen from FIG. 2 to FIG. 10 and Table 1, the conjugated polymer materials can adjust the light absorption range from the visible light region to the near-infrared region according to different A² and A³ structures, that is, the energy gap can vary from 1.76 to 0.74 eV. That is to say, the conjugated polymer material of the present invention can design and control the energy gap of the material to meet different application fields. In other words, the material energy gap of the conjugated polymer material of the present invention can be adjusted to corresponding suitable specifications for different applications, and high-efficiency organic optoelectronic devices can be produced with corresponding N-type materials, for example, high performance OPV or high detection OPD, etc., but not only that.

In this regard, in practical applications, after knowing the basic properties of the material (i.e., the energy gap range), the next step is to screen suitable N-type materials to match these P-type materials and test the effect of the device.

In addition, the solution state test shown in FIG. 2 to FIG. 9 is dissolved in o-xylene, which proves that the conjugated polymer material of the present invention can be coated with o-xylene. In the art, it is an industry trend to use non-halogenated green solvents. Green solvents generally come from renewable resources or can be degraded by soil organisms or other substances, have a short half-life, and are easily decayed into low-toxic and non-toxic substances. Therefore, green solvents are generally less harmful to biological health and the environment than general solvents that are easily chlorinated or highly toxic. Green solvents are also called environmentally friendly solvents. O-xylene is a non-halogen green solvent.

### Preparation and Testing of Organic Photovoltaic (OPV)

A glass coated by a pre-patterned indium tin oxides (ITO) with a sheet resistance of ~15 Q/sq is used as a substrate. The substrate is ultrasonically oscillated in soap deionized water, deionized water, acetone, and isopropanol in sequence, and washed in each step for 15 minutes. The washed substrate is further treated with a UV-ozone cleaner for 30 minutes. The top coat of ZnO is spin coated on the ITO substrate with a spin rate of 5000 rpm for 30 seconds, and then baked at 120° C. in air for 10 minutes to form an electron transporting layer (ETL). The active layer solution was prepared in o-xylene. The active layer includes the aforementioned conjugated polymer materials. To completely dissolve the active layer material, the active layer solution is stirred on a hot plate at 120° C. for at least 1 hour. Then, the active layer solution is returned to the room temperature for spin coating. Finally, the thin film formed by the coated active layer is annealed at 120° C. for 5 minutes, and then transferred to a thermal evaporation machine. A thin layer (8 nm) of MoO₃ is deposited as a hole transporting layer under a vacuum of 3 × 10⁻⁶ Torr, and then a silver layer with a thickness of 100 nm is deposited as an upper electrode. All cells are encapsulated with epoxy resin in the glove box to make organic photovoltaic (ITO/ETL/active layer/MoO₃/Ag). The J-V characteristics of the components is measured by a solar simulator (having a xenon lamp with an AM 1.5 G filter) in air and at room temperature and under AM 1.5 G (100 mW cm⁻²). Herein, a standard silicon diode with a KG5 filter is used as a reference cell to calibrate the light intensity to make the mismatch portion of the spectrum consistent. The J-V characteristics are recorded by a Keithley 2400 source meter instrument. Wherein, organic photovoltaic P1 is prepared with P1 : N1 : PC₆₁BM = 1 : 1 : 0.2, with a concentration of 7 mg/mL in o-xylene; organic photovoltaic P2 is prepared with P2 : N1: PC₆₁BM = 1 : 1 : 0.2, with a concentration of 14 mg/mL in o-xylene. The thicknesses of the above-mention active layers are about 100 nm, and the structures of the organic photovoltaics are glass/ITO/ETL/ATL/MoO₃/Ag.

It should be noted here that, in practical applications, the first electrode preferably has good light transmittance. The first electrode is usually made of a transparent conductive material, preferably selected from one of the following conductive material groups: indium oxide, tin oxide, halogen-doped tin oxide derivative (Florine Doped Tin Oxide, FTO), or composite metal oxides such as Indium Tin Oxide (ITO) and Indium Zinc Oxide (IZO). The material of the second electrode is a conductive metal, preferably silver or aluminum, more preferably silver. Suitable and preferred materials for ETL include, but are not limited to, metal oxides such as ZnOₓ, aluminum doped ZnO (AZO), TiOₓ or nanoparticles thereof, salts (such as LiF, NaF, CsF, CsCO₃), amines (such as primary amines, secondary or tertiary amines), conjugated polymer electrolytes (such as polyethyleneimine), conjugated polymers (such as poly[3-(6-trimethylammoniumhexyl)thiophene], poly(9,9)-Bis(2-ethylhexyl-fluorene)-b-poly[3-(6-trimethylammoniumhexyl)thiophene] or poly[(9,9-bis(3'-(N,N-dimethylamino))propyl)-2,7-fluorene)-alt-2,7-(9,9-dioctylfluorene)], and organic compounds such as tris(8-quinolinyl)-aluminum(III)(Alq₃), 4,7-diphenyl-1,10-phenanthroline), or a combination of one or more of the foregoing. Suitable and preferred materials for HTL include, but are not limited to metal oxides such as ZTO, MoOₓ, WOₓ, NiOₓ or nanoparticles thereof, conjugated polymer electrolytes such as PEDOT:PSS, polymeric acids such as polyacrylates, conjugated polymers such as polytriarylamine (PTAA), insulating polymers such as Nafion films, polyethyleneimine or polystyrene sulfonates, organic compounds such as N,N′ -diphenyl-N,N′ -Bis(1-naphthyl)(1,1’-biphenyl)-4,4’-diamine (NPB), N,N′-diphenyl-N,N′-(3-methylbenzene base)-1,1’-biphenyl-4,4’-diamine (TPD), or a combination of one or more of the above.

Wherein, the structure of N1, N2 and PC₆₁BM is as follows:

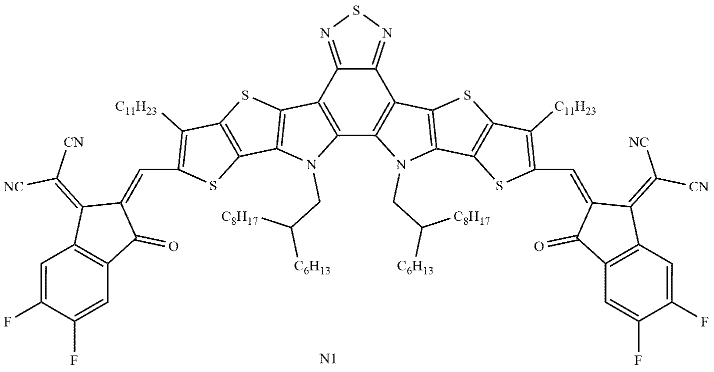

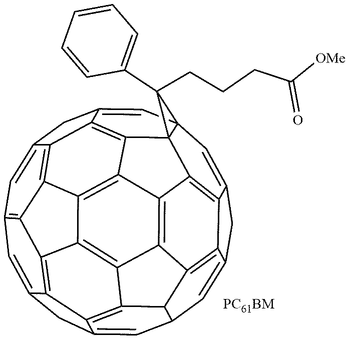

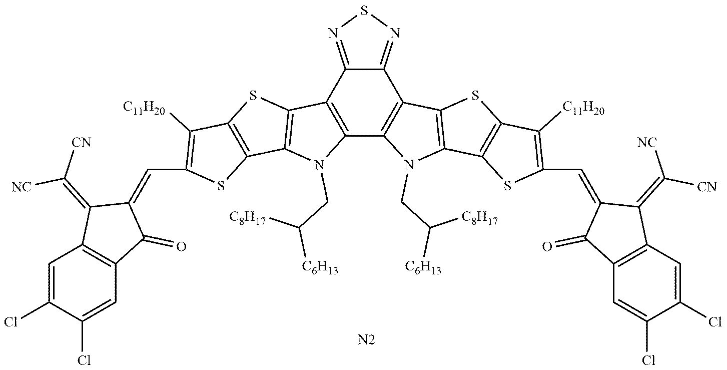

Efficiency analysis of the organic photovoltaics:

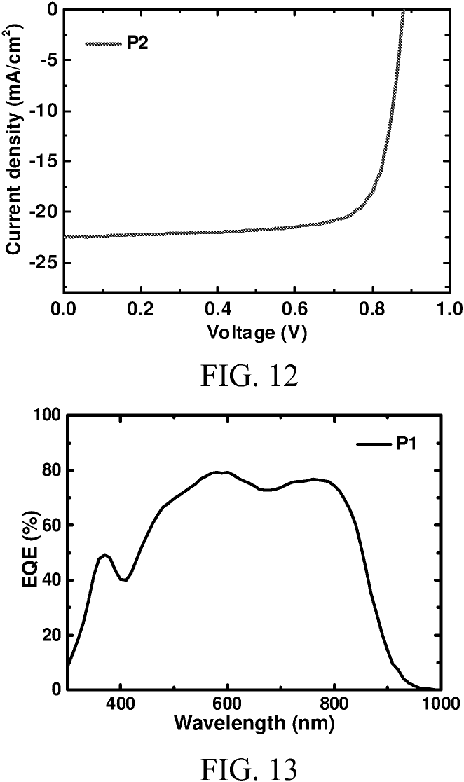

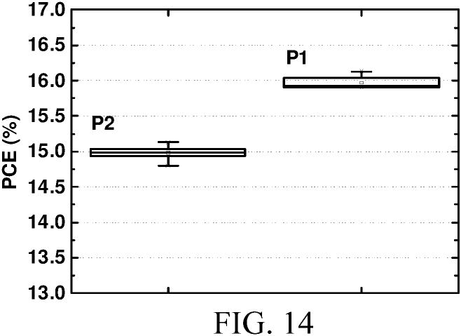

Please refer to FIG. 11 to FIG. 14 and Table 2. FIG. 11 shows a J-V diagram of an embodiment P1 of the organic photovoltaic of the present invention. FIG. 12 shows a J-V diagram of an embodiment P2 of the organic photovoltaic of the present invention. FIG. 13 shows test results of the external quantum efficiency (EQE) of the embodiment P1 of the organic photovoltaic of the present invention. FIG. 14 shows a PCE error bar diagram of the embodiments P1 and P2 of the organic photovoltaics of the present invention. Table 2 shows the device efficiency test results of P1 and P2, which are specific embodiments of the organic photovoltaics of the present invention.

Table 2

The device efficiency test results of P1 and P2, which are specific embodiments of the organic photovoltaics of the present invention

| Electron donor | Electron acceptor 1 | Electron acceptor 2 | V_{oc} (V) | J_{sc} (mA/cm²) | FF (%) | PCE (%) | PCE_{avg} (%) |
|---|---|---|---|---|---|---|---|
| P1 | N1 | PC₆₁BM | 0.87 | 24.73 | 75.15 | 16.13 | 15.97 |
| P2 | N1 | PC₆₁BM | 0.88 | 22.46 | 76.51 | 15.13 | 14.98 |

As shown in Table 2 and FIG. 11 to FIG. 13, the organic photovoltaics prepared by the conjugated polymer materials P1 and P2 of the present invention and the acceptor materials N1 and PC₆₁BM: the organic photovoltaics P1 and P2 both have an energy conversion efficiency (PCE) of more than 15% under the use of a halogen-free solvent. Because the conjugated polymer material of the present invention has good photoelectric conversion efficiency and does not use highly toxic halogen-containing solvents in the component manufacturing process, it has great potential in large-scale production applications. In addition, as shown in FIG. 14, it can be seen that the error bar between the organic photovoltaics P1 and P2 in each test data is small. In other words, each test result is very similar, which means that the organic photovoltaics P1 and P2 of the present invention have good material stability. This also means that the properties of the conjugated polymer material of the present invention are beneficial to obtain good and stable film quality, so that the organic photovoltaic manufacturing process is stable.

### Preparation and Testing Of Organic Detector (OPD)

A glass coated by a pre-patterned indium tin oxides (ITO) with a sheet resistance of ~15 Q/sq is used as a substrate. The substrate is ultrasonically oscillated in soap deionized water, deionized water, acetone, and isopropanol in sequence, and washed in each step for 15 minutes. The washed substrate is further treated with a UV-ozone cleaner for 30 minutes. The top coat of AZO (Aluminum-doped zinc oxide) solution is spin coated on the ITO substrate with a spin rate of 3000 rpm for 40 seconds, and then baked at 120° C. in air for 5 minutes to form an electron transporting layer (ETL). The active layer solution was prepared in o-xylene. The active layer includes the aforementioned conjugated polymer materials. To completely dissolve the active layer material, the active layer solution is stirred on a hot plate at 100° C. for at least 1 hour. Then, the active layer solution is returned to the room temperature for spin coating. Finally, the thin film formed by the coated active layer is annealed at 100° C. for 5 minutes, and then transferred to a thermal evaporation machine. A thin layer (8 nm) of MoO₃ is deposited as a hole transporting layer under a vacuum of 3 × 10⁻⁶ Torr, and then a silver layer with a thickness of 100 nm is deposited as an upper electrode. All cells are encapsulated with epoxy resin in the glove box to make organic photovoltaic (ITO/ETL/active layer/MoO₃/Ag). Dark current (ID) in the absence of light is measured by a Keithley™ 2400 source meter. The photocurrent (Iph) characteristics of organic photodetectors is measured by a solar simulator (having a xenon lamp with an AM 1.5 G filter) in air and at room temperature and under AM 1.5 G (100 mW cm⁻²). Here, a standard silicon diode with a KG5 filter is used as a reference cell to calibrate the light intensity to make the mismatch portion of the spectrum consistent. The external quantum efficiency (EQE) is measured by an external quantum efficiency measuring instrument, the measurement range is 300-1800 nm (bias voltage is 0~-8 V), and the light source calibration uses silicon (300-1100 nm) and germanium (1100-1800 nm). Wherein, organic photodetector P4 is prepared with P4 : N2 = 1 : 1, with a concentration of 14 or 18 mg/mL in o-xylene; organic photodetector P7 is prepared with P7 : N2 = 1 : 1, with a concentration of 10 mg/mL in o-xylene; organic photodetector P8 is prepared with P8 : N2 = 1 : 1, with a concentration of 12 mg/mL in o-xylene. The structures of the organic photodetectors are glass/ITO/AZO/ATL/MoO₃/Ag.

### Efficiency Analysis of the Organic Photodetectors

The performance analysis of the organic optoelectronic device of the present invention is mainly to analyze the external quantum efficiency (EQE) and dark current (J_{d}).

Generally speaking, quantum efficiency (QE) refers to external quantum efficiency (EQE). The quantum efficiency/spectral response reflects the photoelectric conversion efficiency of organic optoelectronic devices for different wavelengths, that is, the ability to effectively convert photons into electrons when illuminated. The conversion efficiency of organic optoelectronic devices is affected by its own material, process, structure and other factors, so that different wavelengths have different conversion efficiencies. In organic photodetector applications, the higher the external quantum efficiency (EQE), the better signal of the organic photodetector.

Dark current (J_{d}), also known as no-illumination current, refers to the current that flows in an optoelectronic device in the absence of light irradiation. In the dark current test, a bias voltage is applied when the organic optoelectronic device is not illuminated. In the application of the organic photodetector, if the generated current is larger, the noise in the organic photodetector is larger.

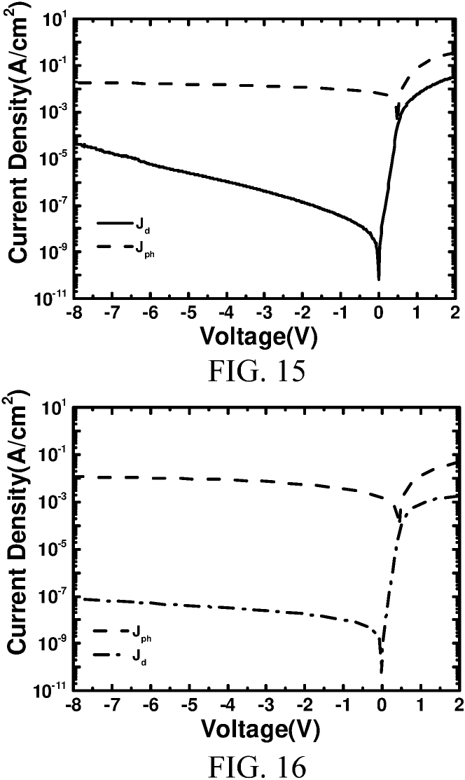

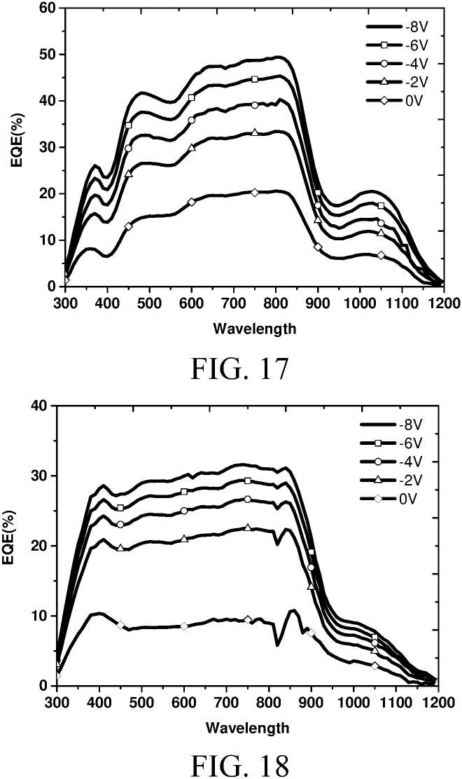

Please refer to FIG. 15 to FIG. 18 and Table 3. FIG. 15 shows a J-V diagram of an embodiment P4 of the organic photodetector of the present invention (the active layer thickness is 100 nm). FIG. 16 shows a J-V diagram of the embodiment P4 of the organic photodetector of the present invention (the active layer thickness is 450 nm). FIG. 17 shows test results of the external quantum efficiency (EQE) of the embodiment P4 of the organic photodetector of the present invention (the active layer thickness is 100 nm). FIG. 18 shows test results of the external quantum efficiency (EQE) of the embodiment P4 of the organic photodetector of the present invention (the active layer thickness is 450 nm). Table 3 shows the device efficiency test results of the embodiment P4 of the organic photodetector of the present invention with different thicknesses of the active layer.

Table 3

The device efficiency test results of the embodiment P4 of the organic photodetector of the present invention with different thicknesses of the active layer

| | | |
|---|---|---|
| Electron donor | P4 | P4 |
| Electron acceptor | N2 | N2 |
| D : A | 1 : 1 | 1 : 1 |
| Thickness of active | 100 | 450 |
| layer (nm) | | |
| J_{d}@-0.5V (A/cm²) | 1.37x10⁻⁸ | 6.08x10⁻⁹ |
| J_{d}@-1V (A/cm²) | 3.49x10⁻⁸ | 1.03x10⁻⁸ |
| J_{d}@-2V (A/cm²) | 1.36x10⁻⁷ | 1.77x10⁻⁸ |
| J_{d}@-4V (A/cm²) | 1.06x10⁻⁶ | 3.20x10⁻⁸ |
| EQE (%) | 13.7% @-4V at 1050 nm | 6.1% @-4V at 1050 nm |
| Detectivity (Jones) | 1.9x10¹¹ @-4V at 1050 nm | S.1x10¹¹ @-4V at 1050 nm |
| Reference | The present invention | The present invention |

As shown in Table 3, FIG. 15 and FIG. 16, the EQE results of the organic photodetectors P4 prepared by P4 and N2 is good at 1050 nm, and can reach 20% under -8 V bias. In addition, when the thickness of the active layer is increased from 100 nm to 450 nm, the dark current of the organic photodetectors P4 can be effectively reduced to 3.2×10⁻⁸ A/cm², thereby effectively reducing the noise generated during detection. The detectivity is calculated by the formula, and it can reach 10¹¹ level under different thickness of the active layer, which is the evidence of good detectivity. As shown in FIG. 17 and FIG. 18, the EQE results of the organic photodetectors P4 can also perform well under -8 V bias, which indicates that the organic photodetector of the present invention has a wide range of voltage tolerance. Based on the above experimental results, in addition to being soluble in non-halogen solvents (environmentally friendly solvents), the light absorption range of the conjugated polymer material of the present invention is more than 1000 nm. In addition, the organic photodetectors prepared by the conjugated polymer material has good EQE and dark current performance in both visible light region and infrared region.

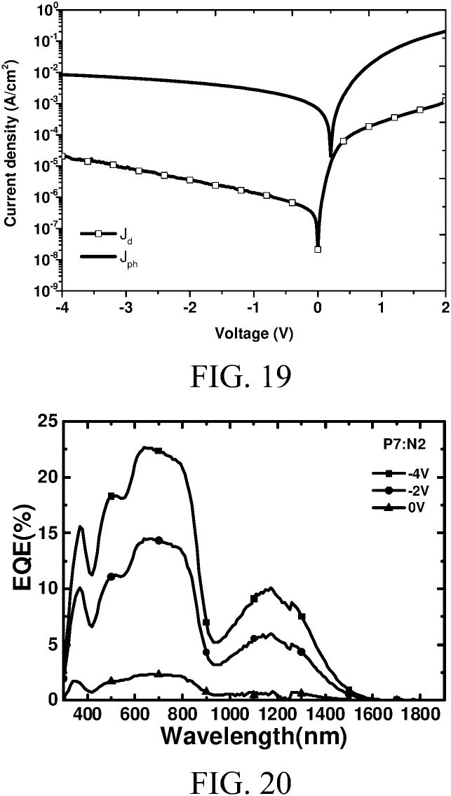

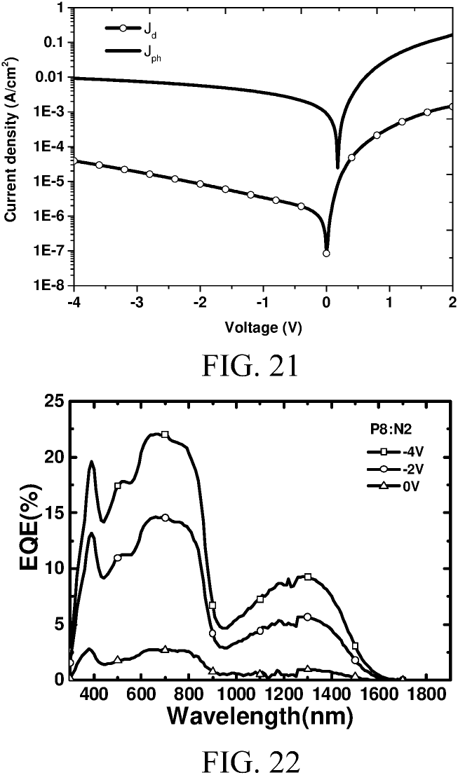

Please refer to FIG. 19 to FIG. 22 and Table 4. FIG. 19 shows a J-V diagram of an embodiment P7 of the organic photodetector of the present invention. FIG. 20 shows test results of the external quantum efficiency (EQE) of the embodiment P7 of the organic photodetector of the present invention. FIG. 21 shows a J-V diagram of an embodiment P8 of the organic photodetector of the present invention. FIG. 22 shows test results of the external quantum efficiency (EQE) of the embodiment P8 of the organic photodetector of the present invention. Table 4 shows the embodiments of the organic photodetectors P7 and P8 of the present invention compared with the performance of the prior art.

Table 4

The embodiments of the organic photodetectors P7 and P8 of the present invention compared with the performance of the prior art

| | | | | |
|---|---|---|---|---|
| Electron donor | P7 | P8 | TQ-T | DPP |
| Electron acceptor | N2 | N2 | Y6 | DTT |
| D : A | 1:1.5 | 1 : 1.5 | 1 : 1 | 1 : 1 |
| Thickness of active layer (nm) | 120 | 140 | 120 | 200 |
| J_{d}@-0.5V (A/cm²) | 7.8x10⁻⁷ | 2.1x10⁻⁶ | | 10-₅ |
| J_{d}@-1V (A/cm²) | 1.4x10⁻⁶ | 3.4x10⁻⁶ | | |
| J_{d}@-2V (A/cm²) | 3.Sx10⁻⁶ | 8.4x10⁻⁶ | 4.3x10⁻⁵ | |
| J_{d}@-4V (A/cm²) | 2,1 x10⁻⁵ | 3.9x10⁻⁵ | | |
| EQE (%) | 5.4% @-4V at 1350 nm | 8.7% @-4V at 1350 nm | ∼0.5% @-2V at 1350 nm | |
| Detectivity (Jones) | 2.2x10¹⁰ @-4V at 1350 nm | 2.7x10¹⁰ @-4V at 1350 nm | 10⁸ @-2V at 1350 nm | 10⁹ @-0.1V at 1200 nm |
| Reference | The present invention | The present invention | Small 2022, 2200580 | Adv. Sci. 2020, 7, 2000444 |

Wherein, the structures of TQ-T, Y6, DPP and DTT is as follows:

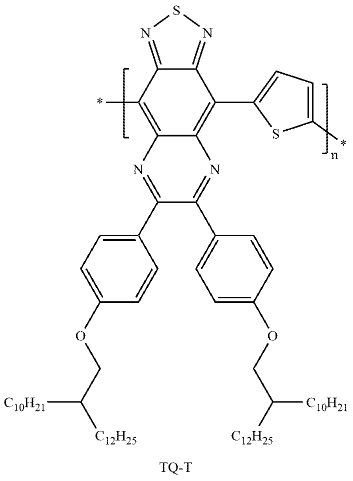

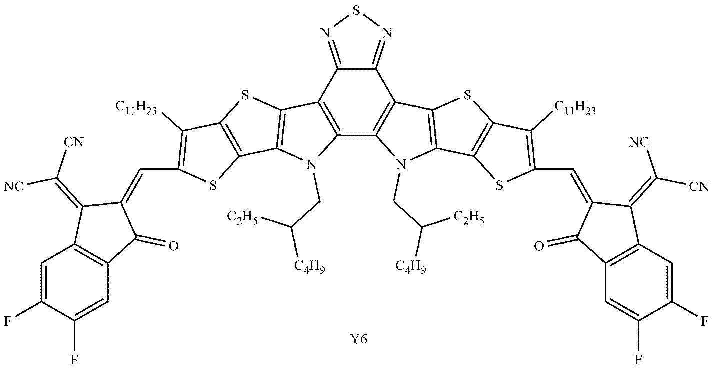

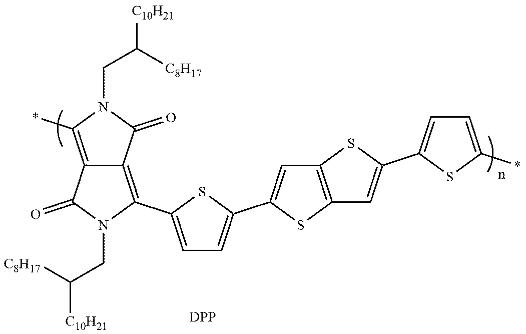

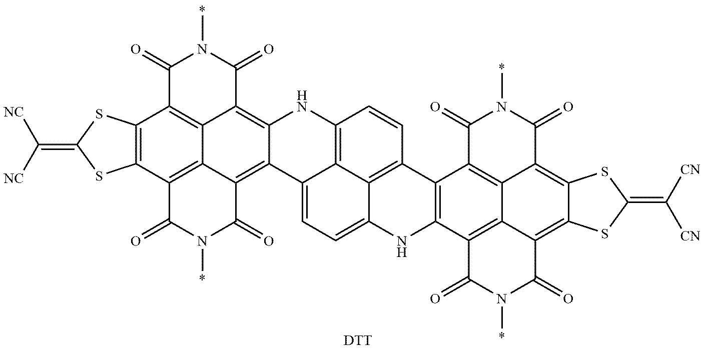

As shown in FIG. 19 to FIG. 22 and Table 4, the organic photodetectors P7 and P8 prepared by P7 and P8 with N2 as N-type materials, respectively. The EQE results of the organic photodetectors P7 and P8 are 5.4% and 8.7% at 1350 nm, respectively. Dark current reaches a level of 10⁻⁶ at -2V and a level of 10⁻⁵ at -4V. The detectivity of the organic photodetectors P7 and P8 are converted to 2.2×10¹⁰ and 2.7×10¹⁰ (Jones), respectively. It can be seen that, compared with the prior art, the organic photodetectors P7 and P8 have good performance whether in terms of detectivity, dark current or EQE, they are much higher than those in the prior art literature. Taking into account various embodiments of the present invention, from the adjustment and control of the energy level of material to the back-end application in different fields, all of these prove that the materials of the present invention are diverse. The wavelength response range of the organic photodetector of the present invention extends from visible light to infrared region, which solves the defect that conventional materials cannot have such a wide range of designs at the same time.

As shown in Table 4, Small 2022, 2200580 used the non-fullerene acceptor Y6 and TQ-T as the P-type material for OPD element fabrication. Compared with the previous case, the EQE and dark current results of the organic photodetectors P7 and P8 of the present invention are more than 10 times higher than the previous case, and the detectivity is higher than 100 times. It can be seen that although the Y6 structure of the previous case is similar to the N-type structure used in the present invention, the device efficiency is very different due to the difference of the P-type material. While another previous case, Adv. Sci. 2020, 7, 2000444, also used non-fullerene acceptors with DPP as P-type materials, the dark current and the detectivity of the organic photodetectors P7 and P8 of the present invention are obviously better than those of the previous literature.

Based on the above experimental results, the conjugated polymer material of the present invention can not only dissolve in a non-halogen solvent (environmentally friendly solvent), but also can adjust the energy gap of the conjugated polymer material according to the structure of A² and A³. Then, its absorption characteristics and spectral appearance can be adjusted.

It should be reminded that, if the substituents in the above description are not clearly stated, the substituents are independently selected from the group consisting of: C1-C30 alkyl, C3-C30 branched alkyl, C1-C30 silyl, C2-C30 ester, C1-C30 alkoxy, C1-C30 alkylthio, C1-C30 haloalkyl, C2-C30 olefin, C2-C30 alkyne, C2-C30 cyano-containing carbon chain, C1-C30 nitro-containing carbon chain, C1-C30 hydroxy-containing carbon chain, C3-C30 keto-containing carbon chain, halogen, cyano and hydrogen.

With the detailed description of the above embodiments, it is hoped that the features and spirit of the present invention can be more clearly described, and the scoped of the present invention is not limited by the embodiments disclosed above. On the contrary, the intention is to cover various changes and equivalent arrangements within the scope of the patents to be applied for in the present invention.

What is claimed is:

1. A conjugated polymer material, comprising a structure of Formula I: 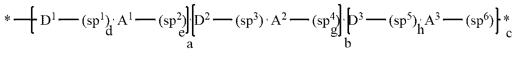
wherein 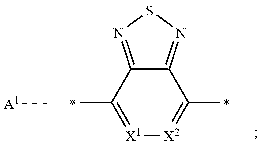
wherein X¹ and X² are the same or different, and independently selected from the group consisting of: N, CH and -CR¹, R¹ is selected from the group consisting of: halogen, -C(O)R^{x1}, -CF₂R^{x1} and -CN, and R^{x1} is selected from the group consisting of: C1-C20 alkyl and C1-C20 haloalkyl;
A² and A³ being the same or different electron-withdrawing groups, the electron-withdrawing groups comprising a polycyclic structure which comprises at least one five-member ring and at least one six-member ring, or a polycyclic structure which comprises at least two five-member rings, and A² and A³ are not simultaneously the same as A¹;
D¹, D² and D³ being the same or different electron-donating groups, and independently selected from the group consisting of: aromatic ring with or without substituent, fused ring with or without substituent, heterocyclic ring with or without substituent, and fused heterocyclic ring with or without substituent;
sp¹ to sp⁶ being the same or different, and independently selected from the group consisting of: aromatic ring with or without substituent, and heterocyclic ring with or without substituent;
a, b and c being real numbers, and 0 < a ≦ 1, 0 ≦ b ≦ 1, 0 ≦ c ≦ 1, a+b+c=1; and
d, e f, g, h and i being the same or different, and independently selected from 0, 1 and 2.

2. The conjugated polymer material of claim 1, wherein b and c are not 0 at the same time.

3. The conjugated polymer material of claim 1, wherein a is in a range from 0.1 to 0.9.

4. The conjugated polymer material of claim 1, wherein D¹, D² and D³ respectively comprise the following structures of fused ring or fused heterocyclic ring having 11 to 24 members: 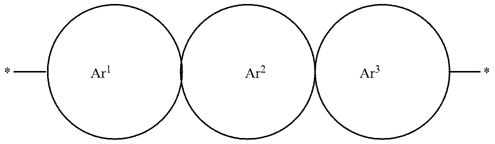
wherein Ar¹, Ar² and Ar³ are the same or different, and independently selected from the group consisting of: five-member aromatic ring with or without substituent, five-member heterocyclic ring with or without substituent, six-member aromatic ring with or without substituent, and six-member heterocyclic ring with or without substituent.

5. The conjugated polymer material of claim 1, wherein D¹, D² and D³ are independently selected from the group consisting of the following structures: 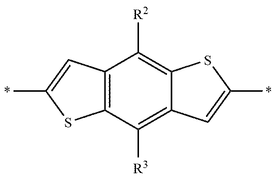 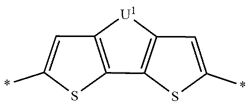 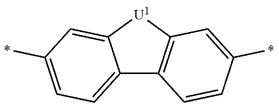
wherein R² and R³ are the same or different, and independently selected from the group consisting of: H, F, R^{x2}, -OR^{x2}, -SR^{x2}, -C(=O)R^{x2}, -C(=O)-OR^{x2} and -S(=O)₂R^{x2}, R^{x2} is selected from the group consisting of: C1-C30 alkyl with or without substituent, and the substituent is independently selected from the group consisting of: O, S, aromatic ring and heterocyclic ring; and
U¹ is selected from the group consisting of: CR⁴R⁵, SiR⁴R⁵, GeR⁴R⁵, NR⁴ and C=O, R⁴ and R⁵ are the same or different, and independently selected from the group consisting of: C1-C30 alkyl with or without substituent, and the substituent is independently selected from the group consisting of: O, S, aromatic ring and heterocyclic ring.

6. The conjugated polymer material of claim 1, wherein A² and A³ are the electron-withdrawing groups with or without substituent, and the structure of the electron-withdrawing groups respectively comprise at least one of the group consisting of: S, N, Si, Se, C=O, CN and SO₂.

7. The conjugated polymer material of claim 6, wherein A² and A³ are independently selected from the following structures and the mirror phase structures thereof: 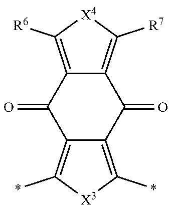 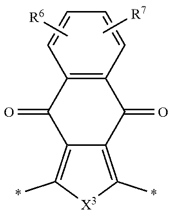 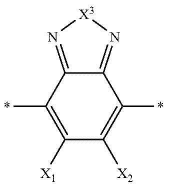 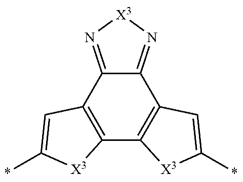 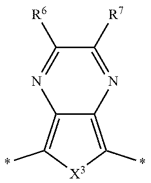 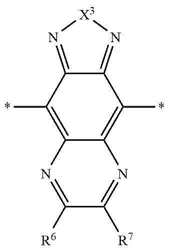 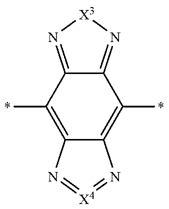 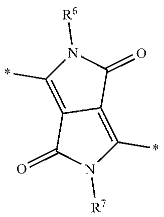
wherein X³ is selected from the group consisting of: S, Se, O, NR^{x3} and R^{x3}, R^{x3} is selected from the group consisting of: C1-C30 alkyl with or without substituent, and the substituent is independently selected from the group consisting of: O, S, aromatic ring and heterocyclic ring;
X⁴ is selected from the group consisting of: S, Se and O; and
R⁶ and R⁷ are the same or different, and independently selected from the group consisting of: H, F, R^{x4}, -OR^{x4}, -SR^{x4}, -C(=O)R^{x4}, -C(=O)-OR^{x4} and -S(=O)₂R^{x4}, R^{x4} is selected from the group consisting of: C1-C30 alkyl with or without substituent, and the substituent is independently selected from the group consisting of: O, S, aromatic ring and heterocyclic ring.

8. The conjugated polymer material of claim 7, wherein A² and A³ are independently selected from the following structures and the mirror phase structures thereof: 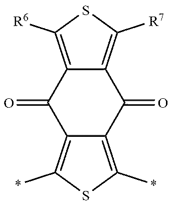 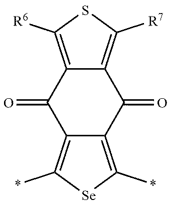 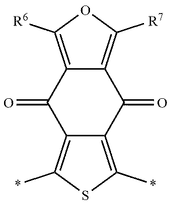 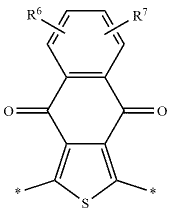 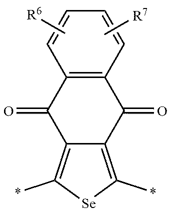 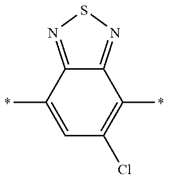 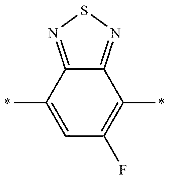 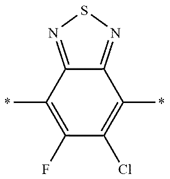 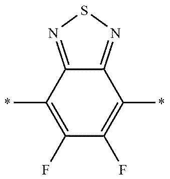 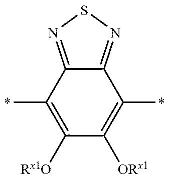 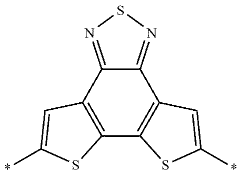 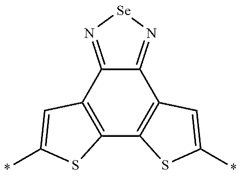 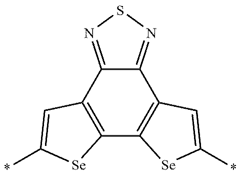 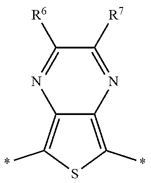 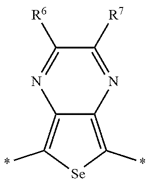 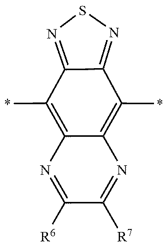 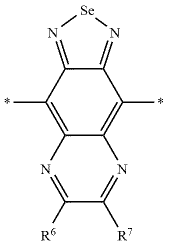 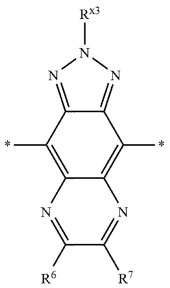 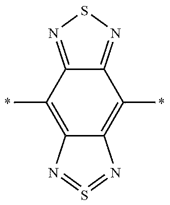 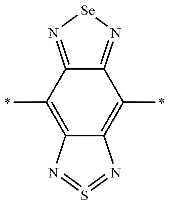 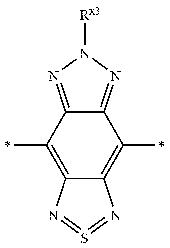 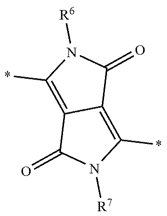
wherein R^{x1} is defined in claim 1, and R⁶, R⁷ and R^{x3} are defined in claim 7.

9. The conjugated polymer material of claim 1, wherein sp¹ to sp⁶ are independently selected from the group consisting of: 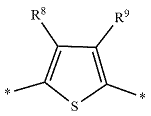 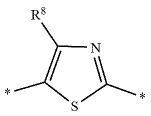 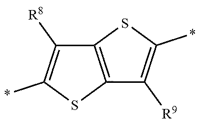 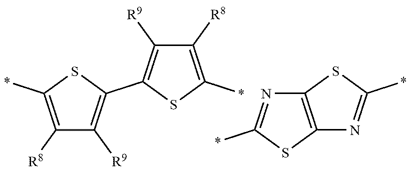
wherein R⁸ and R⁹ are the same or different, and independently selected from the group consisting of: H, F, R^{x5}, -OR^{x5}, -SR^{x5}, -C(=O)R^{x5}, -C(=O)-OR^{x5} and -S(=O)₂R^{x5}, R^{x5} is selected from the group consisting of: C1-C30 alkyl with or without substituent, and the substituent is independently selected from the group consisting of: O, S, aromatic ring and heterocyclic ring.

10. An organic optoelectronic device comprising:
a first electrode including a transparent electrode;
a first carrier transport layer;
an active layer comprising the conjugated polymer material of claim 1;
a second carrier transport layer; and
a second electrode;
wherein the first carrier transport layer is disposed between the first electrode and the active layer, the active layer is disposed between the first carrier transport layer and the second carrier transport layer, and the second carrier transport layer is disposed between the active layer and the second electrode.
